(19) United States
(12) Patent Application Publication
(10) Pub. No.: US 2026/0171152 A1
(43) Pub. Date: Jun. 18, 2026

(54) MEMORY DEVICE AND MEMORY SYSTEM

(71) Applicant: MACRONIX INTERNATIONAL CO., LTD., HSINCHU (TW)

(72) Inventors: Po-Hao TSENG, Taichung City (TW); Tian-Cih BO, Zhubei City (TW)

(21) Appl. No.: 19/231,740

(22) Filed: Jun. 9, 2025

Related U.S. Application Data
(60) Provisional application No. 63/735,309, filed on Dec. 17, 2024.

(51) Int. Cl. G11C 16/04; G11C 16/24; G11C 16/26

(52) U.S. Cl. CPC G11C 16/0433; G11C 16/24; G11C 16/26

(57) ABSTRACT

A memory device includes a plurality of memory blocks configured to store first stored data, and configured to compare the first stored data and first input data to generate a first current signal. The plurality of memory blocks includes a plurality of memory strings coupled with each other, and configured to generate a plurality of string current signals, in which the plurality of memory blocks are configured to sum the plurality of string current signals to generate the first current signal, and a current level of the first current signal is proportional to a difference between an input value of the first input data and a stored value of the first stored data.

### CROSS-REFERENCE TO RELATED APPLICATION

This application claims priority to U.S. Provisional Application No. 63/735,309, filed December, 17, 2024, which is herein incorporated by reference in its entirety.

### BACKGROUND

### Technical Field

The present disclosure relates to a memory technique. More particularly, the present disclosure relates to a memory device and a memory system.

### Description of Related Art

Manhattan distance is a metric used to determine the distance between two data points along a grid-like path, and can be used to measure the sum of the differences across multiple coordinates between two data points. In artificial intelligence applications, Manhattan distance can provide better accuracy. However, memory devices used to compute Manhattan distance may suffer from poor stability and complex operation. Therefore, how to design a memory device that is both stable and easy to operate for computing Manhattan distance is an important issue in this field.

### SUMMARY

The present disclosure provides a memory device. The memory device includes a plurality of memory blocks configured to store first stored data, and configured to compare the first stored data and first input data to generate a first current signal. The plurality of memory blocks includes a plurality of memory strings coupled with each other, and configured to generate a plurality of string current signals, in which the plurality of memory blocks are configured to sum the plurality of string current signals to generate the first current signal, and a current level of the first current signal is proportional to a difference between an input value of the first input data and a stored value of the first stored data.

In some embodiments, the plurality of memory strings are configured to receive a plurality of string select line signals, the plurality of string select line signals include a first string select line signal and a second string select line signal, when the first input data has a first input value, each of the first string select line signal and the second string select line signal has a first voltage level, when the first input data has a second input value, the first string select line signal and the second string select line signal have the first voltage level and a second voltage level, respectively, and when the first input data has a third input value, each of the first string select line signal and the second string select line signal has the second voltage level.

In some embodiments, the second voltage level is smaller than the first voltage level, and the second input value is smaller than the first input value and larger than the third input value.

In some embodiments, the first stored data at least includes a first stored data bit and a second stored data bit, the plurality of memory strings includes a first switch element configured to store the first stored data bit and a second switch element configured to store the second stored data bit, when the first stored data has a first store value, each of the first switch element and the second switch element has a first threshold voltage level, when the first stored data has a second store value, the first switch element and the second switch element has the first threshold voltage level and a second threshold voltage level, respectively, when the first stored data has a third store value, each of the first switch element and the second switch element has the second threshold voltage level.

In some embodiments, the second threshold voltage level is smaller than the first threshold voltage level, and the second store value is smaller than the first store value and larger than the store input value.

In some embodiments, when the input value of the first input data and the store value of the first stored data have a first difference between, each string current signal in a first portion of the plurality of string current signals has a first current level, and a quantity of the string current signals in the first portion is equal to the first difference.

In some embodiments, when the input value of the first input data and the store value of the first stored data have a second difference between, each string current signal in a second portion of the plurality of string current signals has a second current level, and a quantity of the string current signals in the second portion is equal to the second difference, and the second difference is larger than the first difference.

In some embodiments, the plurality of memory strings are configured to receive a plurality of string select line signals, the plurality of string select line signals include a first string select line signal and a second string select line signal, when the first input data has a first input value, the first string select line signal and the second string select line signal has a first voltage level and a second voltage level, respectively, when the first input data has a second input value, the first string select line signal and the second string select line signal have the second voltage level and the first voltage level, respectively.

In some embodiments, the second voltage level is larger than the first voltage level, and the second input value is larger than the first input value.

In some embodiments, the plurality of memory strings include: a first switch element configured to receive the first string select line signal; a second switch element configured to receive the second string select line signal; a third switch element coupled in series with the first switch element; and a fourth switch element coupled in series with the second switch element, in which when the first stored data has a first store value, the third switch element is turned off and the fourth switch element is turned on, and when the first stored data has a second store value, the third switch element is turned on and the fourth switch element is turned off.

In some embodiments, the plurality of memory strings further include: a fifth switch element configured to receive a third string select line signal in the plurality of string select line signals; and a sixth switch element configured to receive a fourth string select line signal in the plurality of string select line signals, in which when the first input data has the first input value, the third string select line signal and the fourth string select line signal has the second voltage level and the first voltage level, respectively.

In some embodiments, the plurality of memory strings further include: a seventh switch element coupled in series with the fifth switch element; and an eighth switch element coupled in series with the sixth switch element; when the first stored data has a third store value, the seventh switch element is turned off and the eighth switch element is turned on, and in which when the first stored data has the second store value, the seventh switch element is turned on and the eighth switch element is turned off.

The present disclosure provides a memory device. The memory device includes a plurality of memory strings coupled with each other, configured to generate a plurality of string current signals, and configured to sum the plurality of string current signals to generate a first current signal, in which the plurality of memory strings include a first switch element group and a second switch element group, the first switch element group is configured to receive a plurality of string select line signals, the plurality of string select line signals are configured to carry first input data, the second switch element group is configured to store first stored data, and a current level of the first current signal is proportional to a difference between an input value of the first input data and a store value of the first stored data.

In some embodiments, the first switch element group includes a first switch element and a second switch element, the second switch element group includes a third switch element and a fourth switch element, and when each of the first switch element and the second switch element is turned on, in response to the input value equal to the store value, each of the third switch element and the fourth switch element is turned off.

In some embodiments, when each of the first switch element and the second switch element is turned on, in response to the input value larger than the store value, the third switch element is turned on, and when each of the first switch element and the second switch element is turned on, in response to the input value smaller than the store value, the fourth switch element is turned on.

The present disclosure provides a memory system. The memory system includes a plurality of first memory block groups and a plurality of second memory block groups. The plurality of first memory block groups are configured to generate a plurality of first current signals, and sum the plurality of first current signals to generate a first bit line signal. The plurality of second memory block groups are configured to generate a plurality of second current signals, and sum the plurality of second current signals to generate a second bit line signal, the plurality of first memory block groups include a third memory block group configured to store first stored data and generate a third current signal in the plurality of first current signals, the plurality of second memory block groups include a fourth memory block group configured to store second stored data and generate a fourth current signal in the plurality of second current signals, a current level of the third current signal is proportional to a first difference between a store value of the first stored data and an input value of first input data, and a current level of the fourth current signal is proportional to a second difference between a store value of the second stored data and the input value of the first input data.

In some embodiments, in response to the first difference smaller than the second difference, the current level of the third current signal is smaller than the current level of the fourth current signal.

In some embodiments, the plurality of first memory block groups further include a fifth memory block group configured to store third stored data and generate a fifth current signal in the plurality of first current signals, a current level of the fifth current signal is proportional to a third difference between a store value of the third stored data and an input value of second input data, and in response to the third difference equal to the first difference, the current level of the fifth current signal is equal to the current level of the third current signal.

In some embodiments, the plurality of first memory block groups further include a sixth memory block group configured to store fourth stored data and generate a sixth current signal in the plurality of first current signals, a current level of the sixth current signal is proportional to a fourth difference between a store value of the fourth stored data and the input value of the second input data, and in response to the fourth difference larger than the second difference, the current level of the sixth current signal is larger than the current level of the fourth current signal.

In some embodiments, in response to the fourth difference smaller than the third difference, the current level of the sixth current signal is smaller than the current level of the fifth current signal.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a part of a memory device, illustrated according to some embodiments of present disclosure.

FIG. 1B to FIG. 1H are schematic diagrams of other conditions of the memory device, illustrated according to some embodiments of present disclosure.

FIG. 1I is a schematic diagram of distributions of threshold voltage levels of the switch elements, illustrated according to some embodiments of present disclosure.

FIG. 2A is a schematic diagram of a memory device, illustrated according to some embodiments of present disclosure.

FIG. 2B is a schematic diagram of further details of the memory device, illustrated according to some embodiments of present disclosure.

FIG. 2C is a schematic diagram of the stored data and the input data of the memory device, illustrated according to some embodiments of present disclosure.

FIG. 2D is a schematic diagram of the input data having various input values, illustrated according to some embodiments of present disclosure.

FIG. 2E is a schematic diagram of the stored data having various store values, illustrated according to some embodiments of present disclosure.

FIG. 2F is a schematic diagram of the stored data and the input data of the memory device, illustrated according to some embodiments of present disclosure.

FIG. 3A and FIG. 3B are schematic diagrams of a memory device, illustrated according to some embodiments of present disclosure.

FIG. 4A is a schematic diagram of a memory system illustrated according to some embodiments of present disclosure.

FIG. 4B is a schematic diagram of further details of the memory system shown in FIG. 4B, illustrated according to some embodiments of present disclosure.

FIG. 4C to FIG. 4F are schematic diagrams of the memory block groups in the memory system, illustrated according to some embodiments of present disclosure.

FIG. 5A to FIG. 5D are schematic diagrams of the stored data and the input data of the memory device shown in FIG. 2A, illustrated according to some embodiments of present disclosure.

FIG. 6A to FIG. 6D are schematic diagrams of the memory block groups shown in FIG. 4C to FIG. 4F performing the search operation, illustrated according to some embodiments of present disclosure.

FIG. 6E is a schematic diagram of further details of the memory system shown in FIG. 4A, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

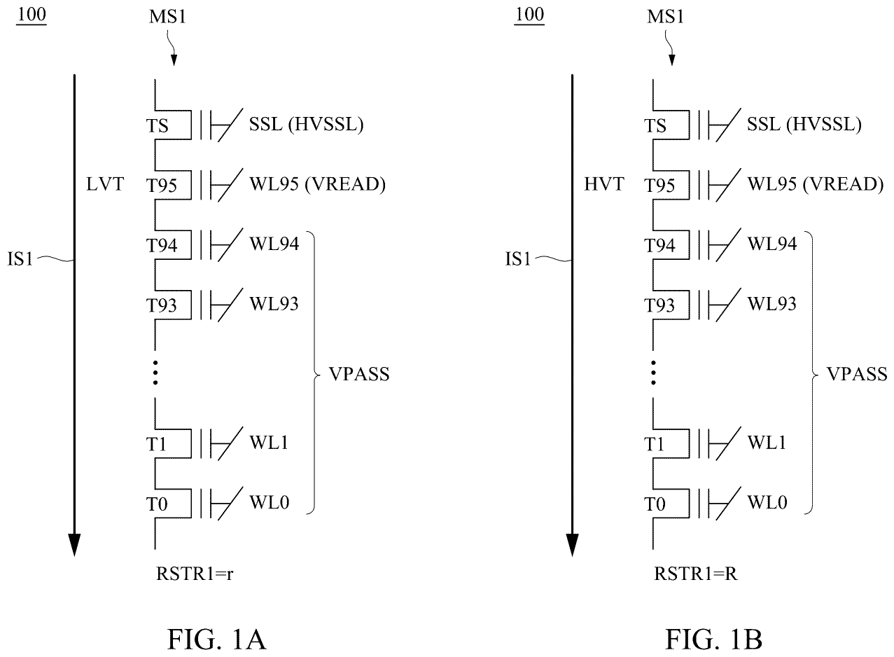

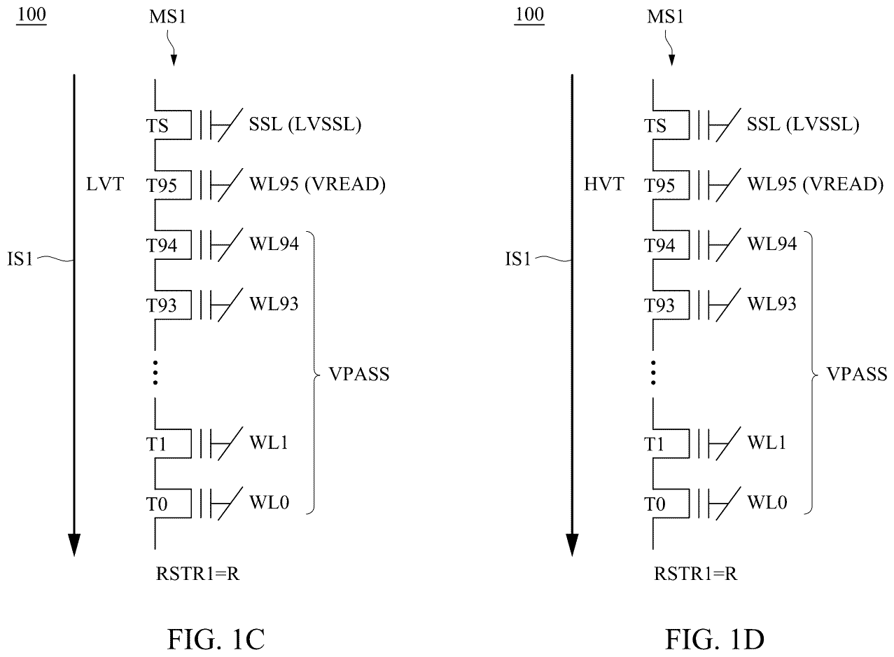

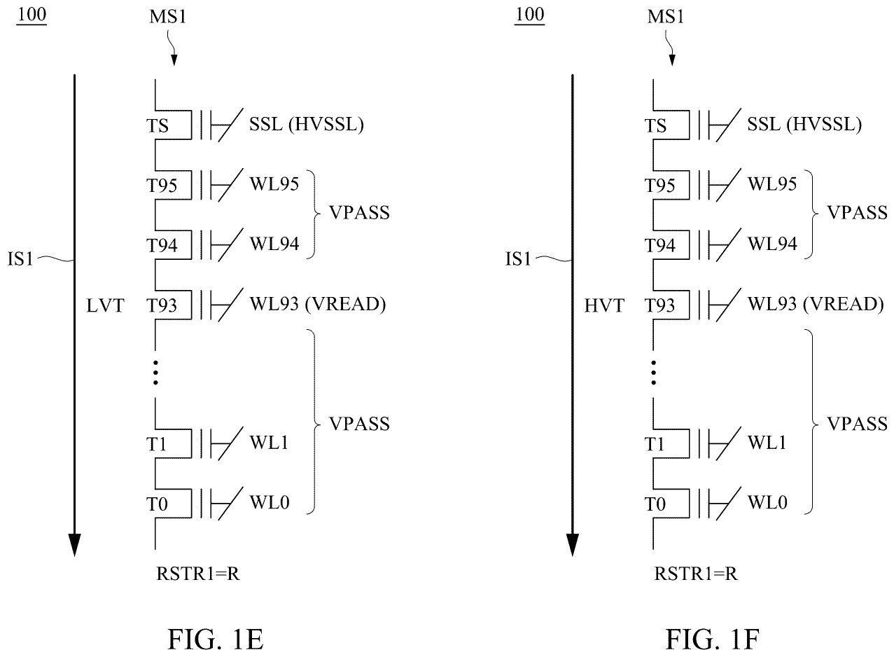

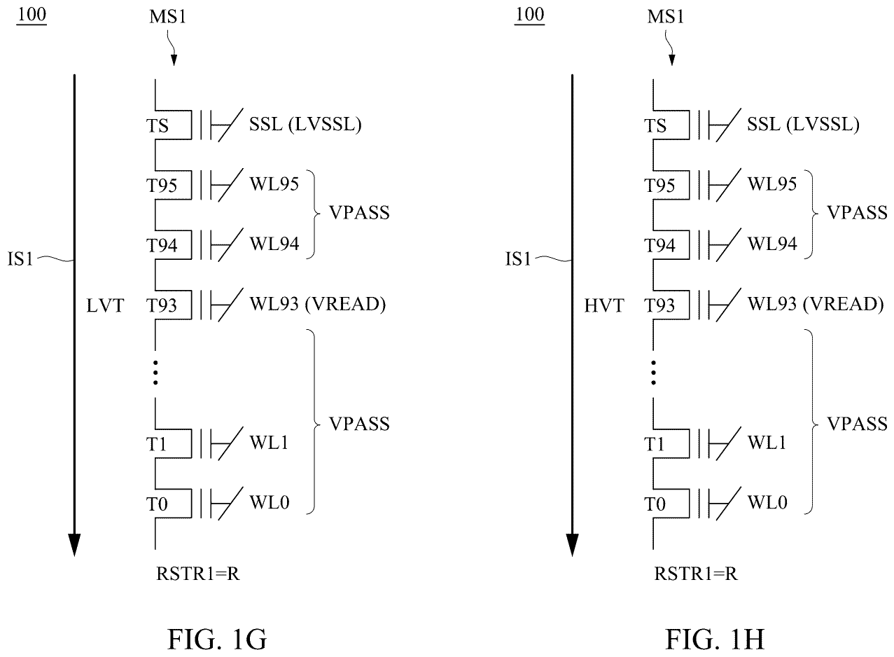

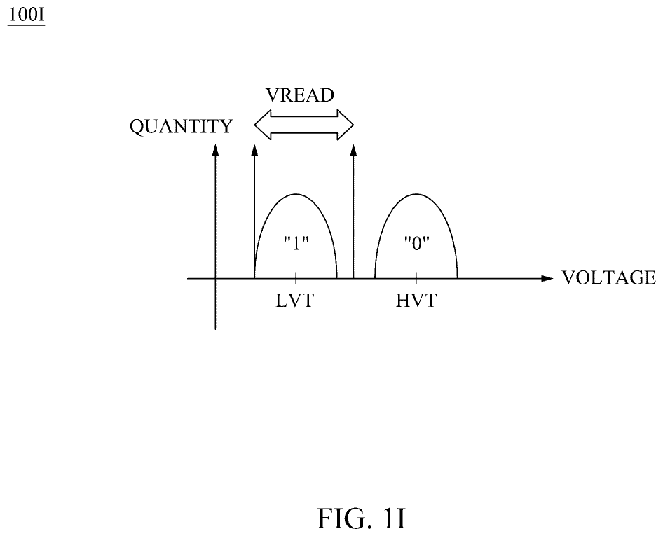

FIG. 1A is a schematic diagram of a part of a memory device 100, illustrated according to some embodiments of present disclosure. In some embodiments, the memory device 100 includes multiple memory strings, such as the memory string MS1. The memory string MS1 is configured to generate a string current signal IS1.

As shown in FIG. 1A, the memory string MS1 can includes multiple switch elements, such as switch elements TS and T0-T95. However, the embodiments of present disclosure are not limited to this. In various embodiments, the memory string MS1 can include various quantities of switch elements, that is, 95 can be substituted with other positive integers.

In some embodiments, the switch elements T0-T95 and TS are coupled in series with each other and are arranged in order. Control terminals of the switch elements T0-T95 and TS are configured to receive the word line signals WL0-WL95 and a string select line signal SSL, respectively.

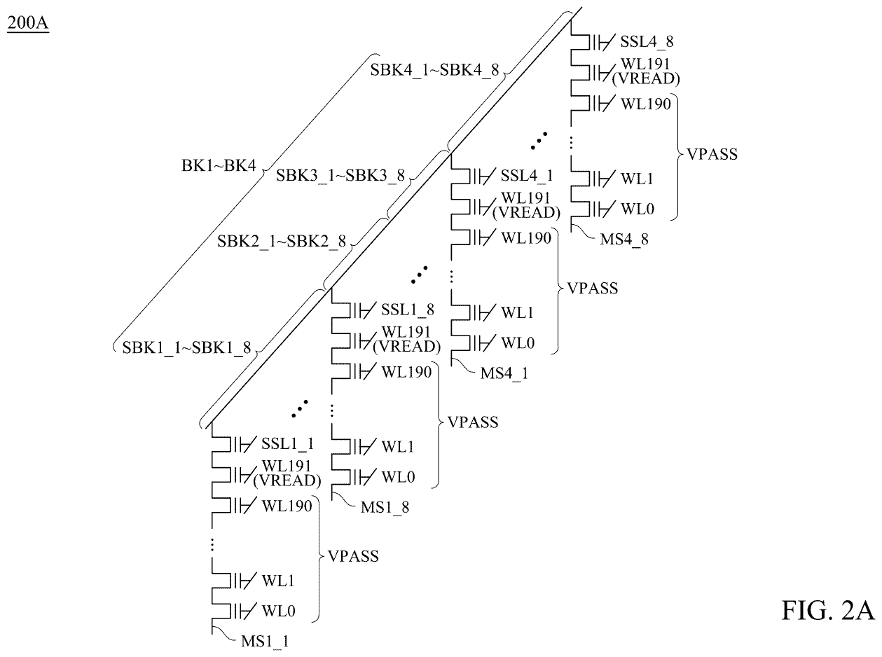

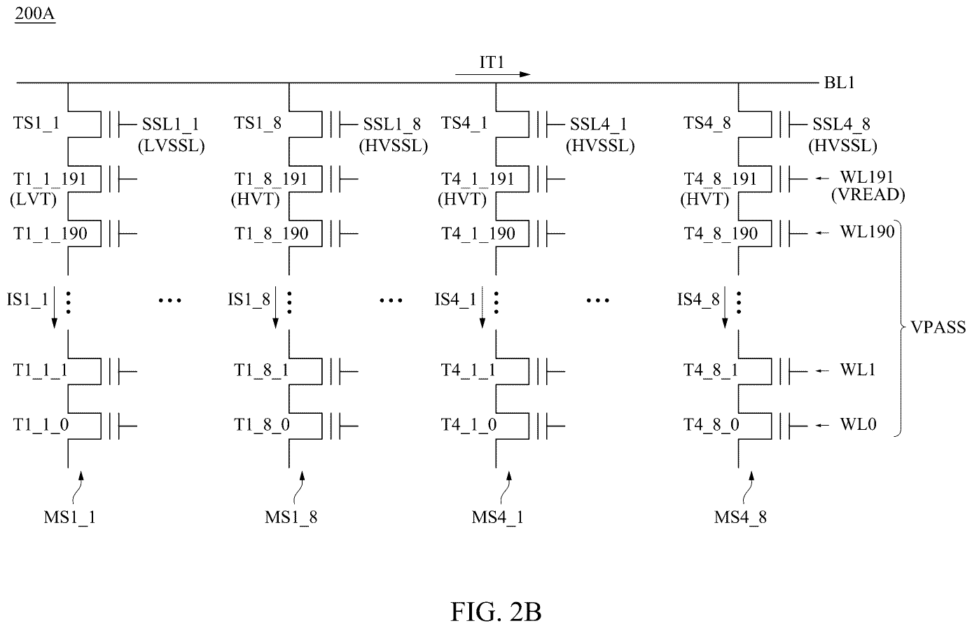

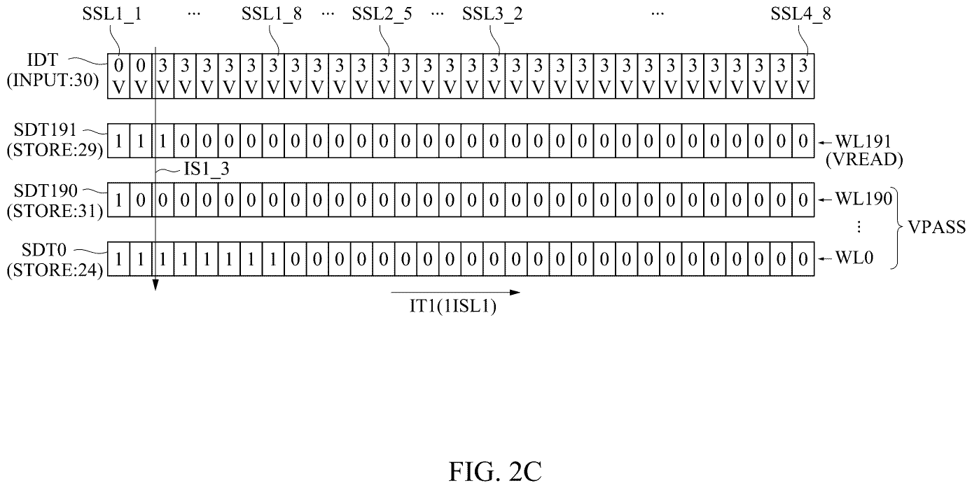

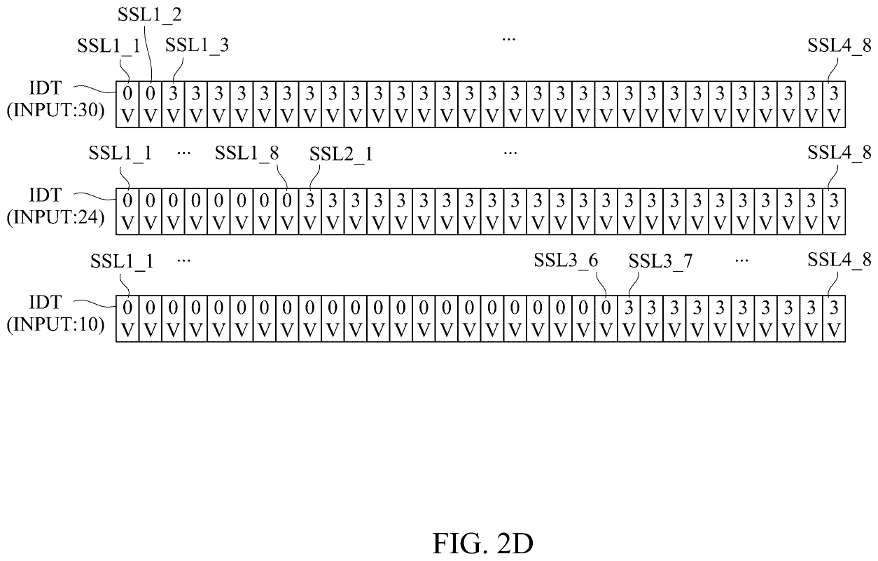

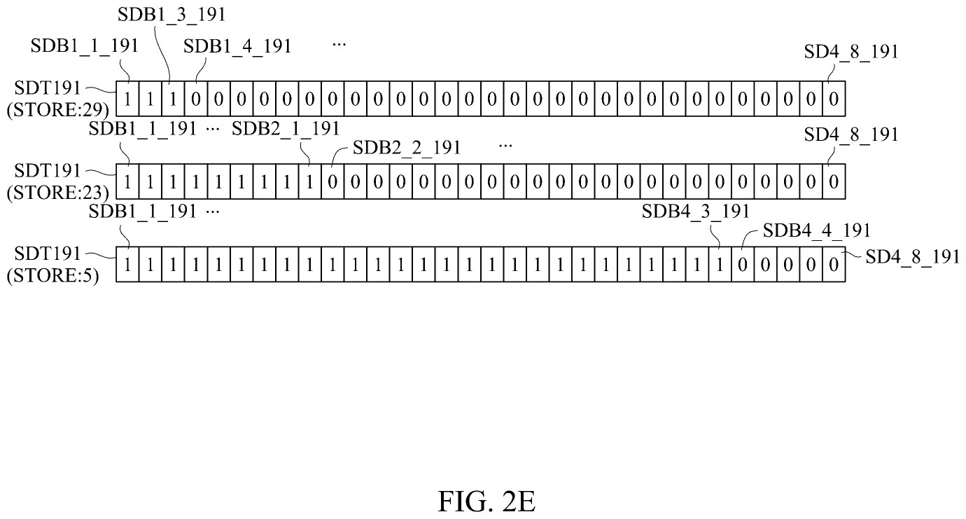

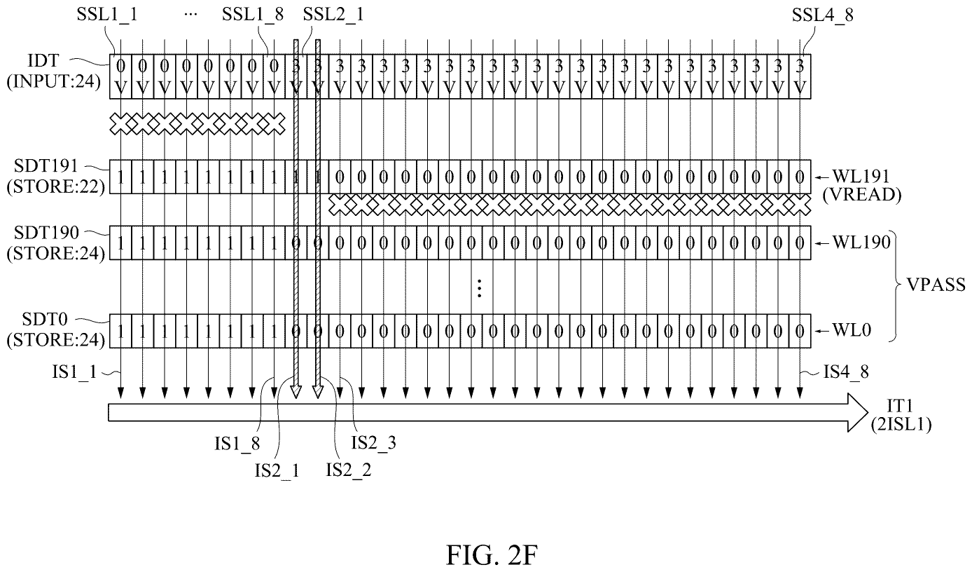

In some embodiments, the switch elements T0-T95 can store corresponding stored data bits, and have corresponding threshold voltage levels HVT or LVT. The threshold voltage level HVT is larger than the threshold voltage level LVT. For example, the threshold voltage level HVT is between 3 volt and 4 volt, and the threshold voltage level LVT is between 0 volt and 1 volt. Details of the switch elements and the stored data bits are further described below with the embodiments associated with FIG. 2C to FIG. 2F.

In some embodiments, the string select line signal SSL can carry a corresponding input bit, and have a corresponding voltage level HVSSL or LVSSL. When the string select line signal SSL has the voltage level HVSSL, the switch element TS is turned on. When the string select line signal SSL has the voltage level LVSSL, the switch element TS is turned off. In some embodiments, the voltage level HVSSL is larger than the voltage level LVSSL. For example, the voltage level HVSSL is approximately equal to 3 volt, and the voltage level LVSSL is approximately equal to 0 volt. Details of the string select line signal SSL and the input bit are further described below with the embodiments associated with FIG. 2C to FIG. 2F.

In various embodiments, one of the word line signals WL0-WL95 has a read voltage level VREAD, to read a corresponding stored data bit. For example, in the embodiment shown in FIG. 1A, the word line signal WL95 has the read voltage level VREAD, to read a read voltage level VREAD, to read corresponding to the switch element T95. In some embodiments, the read voltage level VREAD is larger than the threshold voltage level LVT and is smaller than the threshold voltage level HVT. For example, the read voltage level VREAD can be 2 volt.

Correspondingly, when a switch element has the threshold voltage level LVT and a control terminal of the switch element has the read voltage level VREAD, the switch element is turned on. When a switch element has the threshold voltage level HVT and a control terminal of the switch element has the read voltage level VREAD, the switch element is turned off.

On the other hand, in the embodiment shown in FIG. 1A, each of the word line signals WL0-WL94 has a pass voltage level VPASS, such that each of the switch elements T0-T94 is turned on. The string select line signal SSL has the voltage level HVSSL, such that the switch element TS is turned on. At this moment, a string resistor RSTR1 of the memory string MS1 is determined by the threshold voltage level of the switch element T95. In some embodiments, the pass voltage level VPASS is larger than the threshold voltage level HVT. For example, the pass voltage level VPASS can be between 6 volt and 7 volt.

In the embodiment shown in FIG. 1A, the switch element T95 has the threshold voltage level LVT, such that the string resistor RSTR1 has a resistance r. Correspondingly, the string current signal IS1 has a current level ISL1.

FIG. 1B is a schematic diagram of another condition of the memory device 100, illustrated according to some embodiments of present disclosure. In the embodiment shown in FIG. 1B, each of the word line signals WL0-WL94 has the pass voltage level VPASS, such that each of the switch elements T0-T94 is turned on. The string select line signal SSL has the voltage level HVSSL, such that the switch element TS is turned on.

At this moment, in response to the switch element T95 has the threshold voltage level HVT and the word line signal WL95 has the read voltage level VREAD, the switch element T95 is turned off, such that the string resistor RSTR1 has a resistance R. In which the resistance R corresponds to a memory string with a switch element being turned off. Correspondingly, the string current signal IS1 has a current level ISL2. Referring to FIG. 1A and FIG. 1B, the resistance R is larger than the resistance r. Correspondingly, the current level ISL2 is smaller than the current level ISL1, and can be referred to as the zero current level.

FIG. 1C is a schematic diagram of another condition of the memory device 100, illustrated according to some embodiments of present disclosure. In the embodiment shown in FIG. 1C, each of the word line signals WL0-WL94 has the pass voltage level VPASS, such that each of the switch elements T0-T94 is turned on. In response to the switch element T95 has the threshold voltage level HVT and the word line signal WL95 has the read voltage level VREAD, the switch element T95 is turned off. At this moment, the string select line signal SSL has the voltage level LVSSL, such that the switch element TS is turned off. Correspondingly, the string resistor RSTR1 has the resistance R. Correspondingly, the string current signal IS1 has the current level ISL2.

FIG. 1D is a schematic diagram of another condition of the memory device 100, illustrated according to some embodiments of present disclosure. In the embodiment shown in FIG. 1D, each of the word line signals WL0-WL94 has the pass voltage level VPASS, such that each of the switch elements T0-T94 is turned on. In response to the switch element T95 has the threshold voltage level HVT and the word line signal WL95 has the read voltage level VREAD, the switch element T95 is turned off. At this moment, the string select line signal SSL has the voltage level LVSSL, such that the switch element TS is turned on. Correspondingly, the string resistor RSTR1 has the resistance R. The string current signal IS1 has the current level ISL2.

FIG. 1E is a schematic diagram of another condition of the memory device 100, illustrated according to some embodiments of present disclosure. In the embodiment shown in FIG. 1E, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level LVT and the word line signal WL93 has the read voltage level VREAD, the switch element T93 is turned on. At this moment, the string select line signal SSL has the voltage level HVSSL, such that the switch element TS is turned on. Correspondingly, the string resistor RSTR1 has the resistance r. The string current signal IS1 has the current level ISL1.

FIG. 1F is a schematic diagram of another condition of the memory device 100, illustrated according to some embodiments of present disclosure. In the embodiment shown in FIG. 1F, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level HVT and the word line signal WL93 has the read voltage level VREAD, the switch element T93 is turned off. At this moment, the string select line signal SSL has the voltage level HVSSL, such that the switch element TS is turned on. Correspondingly, the string resistor RSTR1 has the resistance R. The string current signal IS1 has the current level ISL2.

FIG. 1G is a schematic diagram of another condition of the memory device 100, illustrated according to some embodiments of present disclosure. In the embodiment shown in FIG. 1G, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level LVT and the word line signal WL93 has the read voltage level VREAD, the switch element T93 is turned on. At this moment, the string select line signal SSL has the voltage level LVSSL, such that the switch element TS is turned off. Correspondingly, the string resistor RSTR1 has the resistance R. The string current signal IS1 has the current level ISL2.

FIG. 1H is a schematic diagram of another condition of the memory device 100, illustrated according to some embodiments of present disclosure. In the embodiment shown in FIG. 1H, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level HVT and the word line signal WL93 has the read voltage level VREAD, the switch element T93 is turned off. At this moment, the string select line signal SSL has the voltage level HVSSL, such that the switch element TS is turned on. Correspondingly, the string resistor RSTR1 has the resistance R. The string current signal IS1 has the current level ISL2.

FIG. 1I is a schematic diagram 100I of distributions of threshold voltage levels of the switch elements, illustrated according to some embodiments of present disclosure. A horizontal axis in FIG. 1I corresponds to voltages, and a vertical axis in FIG. 1I corresponds to quantities of the switch elements. In some embodiments, the switch elements can have different threshold voltage levels, to store different logic values. As shown in FIG. 1I, when a switch element has the threshold voltage level HVT, the switch element stores the logic value 0. When a switch element has the threshold voltage level LVT, the switch element stores the logic value 1. The read voltage level VREAD is between the threshold voltage levels HVT and LVT.

FIG. 2A is a schematic diagram of a memory device 200A, illustrated according to some embodiments of present disclosure. As shown in FIG. 2A, the memory device 200A includes memory blocks BK1-BK4. The memory block BK1 includes sub-blocks SBK1_1-SBK1_8. The memory block BK2 includes sub-blocks SBK2_1-SBK2_8. The memory block BK3 includes sub-blocks SBK3_1-SBK3_8. The memory block BK4 includes sub-blocks SBK4_1-SBK4_8. However, the embodiments of present disclosure are not limited to this. In various embodiment, the memory device 200A can includes various quantities of memory blocks and sub-blocks. Alternatively stated, 4 and 8 described above can be substituted by other positive integers.

In some embodiments, the 32 sub-blocks SBK1_1-SBK4_8 include 32 memory strings MS1_1-MS4_8, respectively. The memory strings MS1_1-MS4_8 are coupled to each other as a main bit line MBL, and are configured to generate a bit line signal BL1.

As shown in FIG. 2A, each of the memory strings MS1_1-MS4_8 is configured to receive word line signals WL0-WL191. The memory strings MS1_1-MS4_8 are configured to receive string select line signals SSL1_1-SSL4_8, respectively.

In the embodiment shown in FIG. 2A, the memory device 200A performs a read operation to the switch elements corresponding to the word line signal WL191. Correspondingly, the word line signal WL191 has the read voltage level VREAD, and each of the word line signals WL0-WL190 has the pass voltage level VPASS.

Referring to FIG. 1A to FIG. 2A, configurations of each of the memory strings MS1_1-MS4_8 is similar to the configuration of the memory string MS1. Therefore, for brevity, some descriptions are not repeated. Further details of the memory strings MS1_1-MS4_8 are described below with embodiments associated with FIG. 2B.

FIG. 2B is a schematic diagram of further details of the memory device 200A, illustrated according to some embodiments of present disclosure. As shown in FIG. 2B, the memory strings MS1_1-MS4_8 are arranged in order along a horizontal direction. The memory string MS1_1 includes switch elements T1_1_0-T1_1_191 and TS1_1 coupled in series with each other and arranged in order. The memory string MS1_2 includes switch elements T1_2_0-T1_2_191 and TS1_2 coupled in series with each other and arranged in order, and so on. The memory string MS1_8 includes switch elements T1_8_0-T1_8_191 and TS1_8 coupled in series with each other and arranged in order.

Similarly, the memory string MS2_1 includes switch elements T2_1_0-T2_1_191 and TS2_1 coupled in series with each other and arranged in order. The memory string MS2_2 includes switch elements T2_2_0-T2_2_191 and TS2_2 coupled in series with each other and arranged in order, and so on. The memory string MS2_8 includes switch elements T2_8_0-T2_8_191 and TS2_8 coupled in series with each other and arranged in order.

Similarly, the memory string MS3_1 includes switch elements T3_1_0-T3_1_191 and TS3_1 coupled in series with each other and arranged in order. The memory string MS3_2 includes switch elements T3_2_0-T3_2_191 and TS3_2 coupled in series with each other and arranged in order, and so on. The memory string MS3_8 includes switch elements T3_8_0-T3_8_191 and TS3_8 coupled in series with each other and arranged in order.

Similarly, the memory string MS4_1 includes switch elements T4_1_0-T4_1_191 and TS4_1 coupled in series with each other and arranged in order. The memory string MS4_2 includes switch elements T4_2_0-T4_2_191 and TS4_2 coupled in series with each other and arranged in order, and so on. The memory string MS4_8 includes switch elements T4_8_0-T4_8_191 and TS4_8 coupled in series with each other and arranged in order.

In summary, each memory string includes 193 switch elements, such that the 32 memory strings MS1_1-MS4_8 include 193×32 switch elements. However, the embodiments of present disclosure are not limited to this. In various embodiments, 193 and 32 described above can be substituted by other positive integers. For example, in the embodiments shown in FIG. 1A to FIGS. 1H, 193 is substituted by 97.

In some embodiments, control terminals of the switch elements TS1_1-TS4_8 are configured to receive the string select line signals SSL1_1-SSL4_8. Each of control terminals of the switch elements T1_1_0-T4_8_0 is configured to receive the word line signal WL0. Each of control terminals of the switch elements T1_1_1-T4_8_1 is configured to receive the word line signal WL1, and so on. Each of control terminals of the switch elements T1_1_190-T4_8_190 is configured to receive the word line signal WL190. Each of control terminals of the switch elements T1_1_191-T4_8_191 is configured to receive the word line signal WL191.

As shown FIG. 2B, the memory strings MS1_1-MS4_8 are configured to generate string current signals IS1_1-IS4_8, respectively. The memory device 200A is further configured to sum the string current signals IS1_1-IS4_8 to generate a current signal IT1. Alternatively stated, a current level of the current signal IT1 is equal to a summation of current levels of the string current signals IS1_1-IS4_8.

In some embodiments, the switch elements T1_1_0-T4_8_0 are configured to store stored data SDT0. The switch elements T1_1_1-T4_8_1 are configured to store stored data SDT1, and so on. The switch elements T1_1_190-T4_8_190 are configured to store stored data SDT190. The switch elements T1_1_191-T4_8_191 are configured to store stored data SDT191. In summary, the switch elements T1_1_0-T4_8_191 can store the stored data SDT0-SDT191.

In some embodiments, each of the stored data SDT0-SDT191 includes 32 stored data bits. Specifically, the stored data SDT0 includes stored data bits SDB1_1_0-SDB4_8_0. The stored data SDT1 includes stored data bits SDB1_1_1-SDB4_8_1, and so on. The stored data SDT190 includes stored data bits SDB1_1_190-SDB4_8_190. The stored data SDT191 includes stored data bits SDB1_1_191-SDB4_8_191. Correspondingly, the switch elements T1_1_0-T4_8_191 are configured to store the stored data bits SDB1_1_0-SDB4_8_191, respectively.

When a stored data bit has the logic value 0, a corresponding switch element has the threshold voltage level HVT. When a stored data bit has the logic value 1, a corresponding switch element has the threshold voltage level LVT. For example, when the stored data bit SDB1_1_0 has the logic value 0, the switch element T1_1_0 has the threshold voltage level HVT. When the stored data bit SDB1_1_0 has the logic value 1, the switch element T1_1_0 has the threshold voltage level LVT.

In the embodiment shown in FIG. 2B, in response to each of the stored data bits SDB1_1_191-SDB1_3_191 having the logic value 1, each of the switch elements T1_1_191-T1_3_191 has the threshold voltage level LVT. In response to each of the stored data bits SDB1_4_191-SDB4_8_191 having the logic value 0, each of the switch elements T1_4_191-T4_8_191 has the threshold voltage level HVT.

In some embodiments, the stored data SDT0-SDT191 has corresponding store values. In the embodiment shown in FIG. 2B, the store values are equal to a quantity of the stored data bits having the logic value 0 in the corresponding stored data. For example, in response to the stored data SDT0 including 29 stored data bits SDB1_4_191-SDB4_8_191 having the logic value 0, the stored data SDT0 has a store value 29.

On the other hand, the string select line signals SSL1_1-SSL4_8 are configured to carry input data IDT. In response to an input value of the input data IDT, the string select line signals SSL1_1-SSL4_8 have the voltage levels HVSSL or LVSSL.

In the embodiment shown in FIG. 2B, the input value of the input data IDT is equal to a quantity of the string select line signals having the voltage level HVSSL. For example, in response to each of the string select line signals SSL1_1-SSL4_8 having the voltage level HVSSL, the input data IDT has an input value 32. For another example, in response to each of the string select line signals SSL1_3-SSL4_8 having the voltage level HVSSL and each of the string select line signals SSL1_1-SSL1_2 having the voltage level LVSSL, the input data IDT has an input value 30.

FIG. 2C is a schematic diagram of the stored data and the input data of the memory device 200A, illustrated according to some embodiments of present disclosure. In some embodiments, the encoding method of the stored data and the input data are referred to as thermometer encoding.

In the embodiment shown in FIG. 2C, the voltage levels HVSSL and LVSSL are equal to 3 voltage (3V) and 0 voltage (0V), respectively. The input data IDT has the input value 30. The stored data SDT0, SDT190 and SDT191 have a store value 24, a store value 31 and a store value 29, respectively.

In response to the stored data SDT0 having the store value 24, each of the stored data bits SDB1_1_0-SDB1_8_0 has the logic value 1, and each of the stored data bits SDB2_1_0-SDB4_8_0 has the logic value 0. In response to the stored data SDT190 having the store value 31, the stored data bit SDB1_1_190 has the logic value 1, and each of the stored data bits SDB1_2_190-SDB4_8_190 has the logic value 0. In response to the stored data SDT191 having the store value 29, each of the stored data bits SDB1_1_191-SDB1_3_191 has the logic value 1, and each of the stored data bits SDB1_4_191-SDB4_8_191 has the logic value 0.

In the embodiment shown in FIG. 2C, the memory device 200A compares the input data IDT and the stored data SDT191. Correspondingly, each of the word line signals WL0-WL190 has the pass voltage level VPASS, such that corresponding switch elements are turned on. The word line signal WL191 has the read voltage level VREAD, such that each of the switch elements T1_1_191-T1_3_191 is turned on, and each of the switch elements T1_4_191-T4_8_191 is turned off. In response to the switch elements T1_4_191-T4_8_191 being turned off, each of the string current signals IS1_4-IS4_8 has the current level ISL2.

On the other hand, each of the string select line signals SSL1_3-SSL4_8 has the voltage level HVSSL and each of the string select line signals SSL1_1-SSL1_2 has the voltage level LVSSL, such that each of the switch elements TS1_1-TS1_2 is turned off, and each of the switch elements TS1_3-TS4_8 is turned on. In response to the switch elements TS1_1-TS1_2 being turned off, each of the string current signals IS1_1-IS1_2 has the current level ISL2.

At this moment, in response to each of the switch elements TS1_3 and T1_3_0-T1_3_191 being turned on, the string current signal IS1_3 has the current level ISL1, such that the current level of the current signal IT1 is equal to the current level ISL1 multiplied by 1.

When a difference between the input value of the input data IDT and the store value of the stored data SDT191 is larger, a quantity of memory strings with string select signals having the voltage level HVSSL corresponding to stored data bits having the logic value 1 is larger. Alternatively stated, a quantity of the string current signals having the current level ISL1 is proportional to the difference between the input value of the input data IDT and the store value of the stored data SDT191.

In some embodiments, the difference between the input value of the input data IDT and the store value of the stored data SDT191 is referred to as a Manhattan distance between the input data IDT and the stored data SDT191.

In some approaches, a memory device uses word line signals to carry input data to calculate a Manhattan distance. However, the encoding method of the word line signals is complicated, such that the reliability and the robustness are lower.

Compared to above approaches, in the embodiments of present disclosure, the memory device 200A uses the string select line signals SSL1_1-SSL4_8 to carry the input data IDT, and operates by the thermometer encoding, to calculate the Manhattan distance. As a result, the reliability and the robustness are increased.

In the embodiment shown in FIG. 2C, when the store value of the stored data is larger than the input value of the input data, the current signal IT1 has the zero current level. For example, when the input value 30 of the input data IDT and the store value 31 of the stored data SDT190 are compared, each of the word line signals WL0-WL189 and WL191 has the pass voltage level VPASS, such that corresponding switch elements are turned on. The word line signal WL190 has the read voltage level VREAD, such that each of the switch elements T1_2_191-T4_8_191 is turned off, such that each of the string current signals IS1_2-IS4_8 has the current level ISL2. On the other hand, the string select line signals SSL1 has the voltage level LVSSL, such that the string current signal IS1_1 has the current level ISL2. In response to the current level ISL2 is referred to as the zero current level, the current level of the current signal IT1 is equal to the zero current level.

FIG. 2D is a schematic diagram of the input data having various input values, illustrated according to some embodiments of present disclosure. In various embodiments, the input data IDT can have one of the input value 0 to the input value 32. In some embodiments, the input value of the input data IDT is equal to a quantity of the string select line signals having the voltage level HVSSL. In the embodiment shown in FIG. 2D, the voltage levels HVSSL and LVSSL are equal to 3 volt and 0 volt, respectively.

As shown in FIG. 2D, when the input data IDT has the input value 30, each of the select line signals SSL1_1 and SSL1_2 has the voltage level LVSSL, and each of the select line signals SSL1_3-SSL4_8 has the voltage level HVSSL. When the input data IDT has the input value 24, each of the select line signals SSL1_1-SSL1_8 has the voltage level LVSSL, and each of the select line signals SSL2_1-SSL4_8 has the voltage level HVSSL. When the input data IDT has the input value 10, each of the select line signals SSL1_1-SSL3_6 has the voltage level LVSSL, and each of the select line signals SSL3_7-SSL4_8 has the voltage level HVSSL.

FIG. 2E is a schematic diagram of the stored data having various store values, illustrated according to some embodiments of present disclosure. In the embodiment shown in FIG. 2E, the stored data SDT191 is described for example. However, the embodiments of present disclosure are not limited to this. The following descriptions are also suitable for each of the stored data SDT0-SDT190.

In various embodiments, the stored data SDT191 can have one of the store value 0 to the store value 32. In some embodiments, the store value of the stored data SDT191 is equal to a quantity of the stored data bits having the logic value 0. Alternatively stated, the store value of the stored data SDT191 is equal to a quantity of the switch elements having the threshold voltage level HVT.

As shown in FIG. 2E, when the stored data SDT191 has the store value 29, each of the stored data bits SDB1_1_191-SDB1_3_191 has the logic value 1, and each of the stored data bits SDB1_4_191-SDB4_8_191 has the logic value 0. When the stored data SDT191 has the store value 23, each of the stored data bits SDB1_1_191-SDB2_1_191 has the logic value 1, and each of the stored data bits SDB2_2_191-SDB4_8_191 has the logic value 0. When the stored data SDT191 has the store value 5, each of the stored data bits SDB1_1_191-SDB4_3_191 has the logic value 1, and each of the stored data bits SDB4_4_191-SDB4_8_191 has the logic value 0.

FIG. 2F is a schematic diagram of the stored data and the input data of the memory device 200A, illustrated according to some embodiments of present disclosure. In the embodiment shown in FIG. 2F, the voltage levels HVSSL and LVSSL are equal to 3 volt and 0 volt, respectively. The input data IDT has the input value 24. The stored data SDT0, SDT190 and SDT191 have the store value 24, the store value 24 and the store value 22, respectively.

In response to the stored data SDT0 having the store value 24, each of the stored data bits SDB1_1_0-SDB1_8_0 has the logic value 1, and each of the stored data bits SDB2_1_0-SDB4_8_0 has the logic value 0. In response to the stored data SDT190 having the store value 24, each of the stored data bits SDB1_1_190-SDB1_8_190 has the logic value 1, and each of the stored data bits SDB2_1_190-SDB4_8_190 has the logic value 0. In response to the stored data SDT190 having the store value 22, each of the stored data bits SDB1_1_190-SDB2_2_190 has the logic value 1, and each of the stored data bits SDB2_3_190-SDB4_8_190 has the logic value 0.

In the embodiment shown in FIG. 2F, the memory device 200A compares the input data IDT and the stored data SDT191. Correspondingly, each of the word line signals WL0-WL190 has the pass voltage level VPASS, and the word line signal WL191 has the read voltage level VREAD. Correspondingly, each of the switch elements T1_1_191-T2_2_191 is turned on, and each of the switch elements T2_3_191-T4_8_191 is turned off, such that the string current signals IS2_3-IS4_8 are blocked by the switch elements T2_3_191-T4_8_191, respectively. Alternatively stated, each of the string current signals IS2_3-IS4_8 has the current level ISL2.

On the other hand, in response to the input data IDT having the input value 24, each of the string select line signals SSL2_1-SSL4_8 has the voltage level HVT and each of the string select line signals SSL1_1-SSL1_8 has the voltage level LVT, such that each of the switch elements TS1_1-TS1_8 is turned off. At this moment, the switch elements TS1_1-TS1_8 block the string current signals IS1_1-IS1_8, respectively, such that each of the string current signals IS1_1-IS1_8 has the current level ISL2.

At this moment, in response to the string select line signal SSL2_1 having the voltage level HVT and the stored data bit SDB2_1_191 having the logic value 1, the string current signal IS2_1 has the current level ISL1. Similarly, in response to the string select line signal SSL2_2 having the voltage level HVT and the stored data bit SDB2_2_191 having the logic value 1, the string current signal IS2_2 has the current level ISL1. Correspondingly, the current level of the current signal IT1 is equal to the current level ISL1 multiplied by 2, in which 2 represents the difference between the input value 24 of the input data IDT and the store value 22 of the stored data SDT191.

In summary, when a string select line signal has the voltage level HVT and a corresponding stored data bit has the logic value 1, a corresponding string current signal has the current level ISL1. When the difference between the input value of the input data IDT and the store value of the stored data SDT191 is increased, a quantity of the string current signals having the current level ISL1 is increased correspondingly, such that the current level of the current signals IT1 is increased. In contrast, when the difference between the input value of the input data IDT and the store value of the stored data SDT191 is decreased, a quantity of the string current signals having the current level ISL1 is decreased correspondingly, such that the current level of the current signals IT1 is decreased.

In some embodiments, the quantity of the string current signals having the current level ISL1 is equal to the difference between the input value of the input data IDT and the store value of the stored data SDT191. For example, in the embodiment shown in FIG. 2C, the quantity of the string current signal IS1_3 having the current level ISL1 is equal to the difference between the input value 30 and the store value 29. In the embodiment shown in FIG. 2F, the quantity of the string current signals IS2_1 and IS2_2 having the current level ISL1 is equal to the difference between the input value 24 and the store value 22.

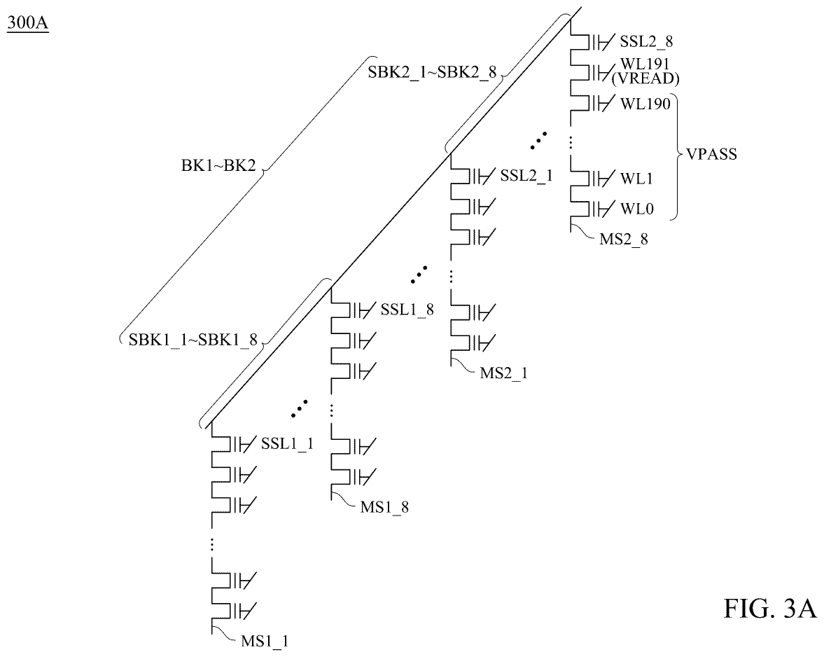

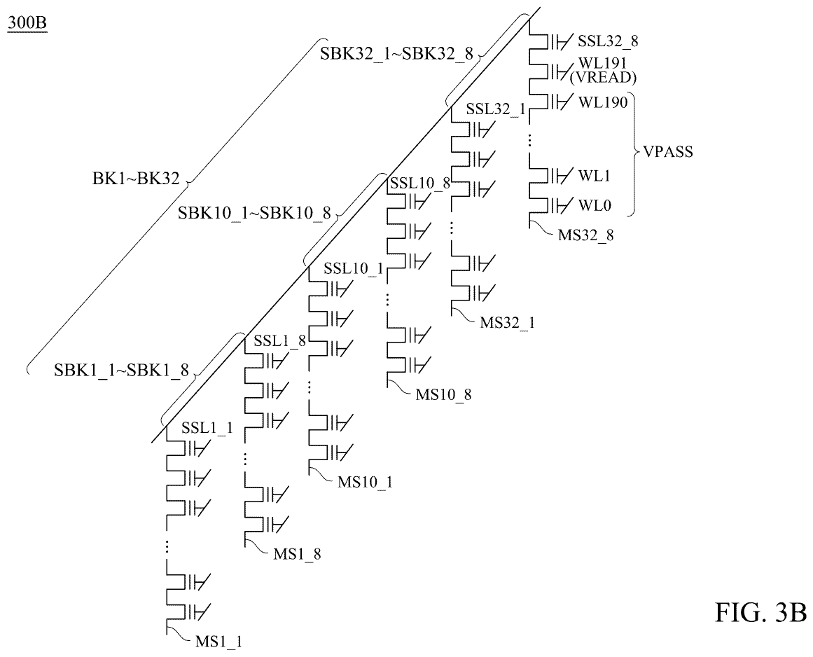

FIG. 3A is a schematic diagram of a memory device 300A, illustrated according to some embodiments of present disclosure. Referring to FIG. 2A, FIG. 2B and FIG. 3A, the memory device 300A is an alternative embodiment of the memory device 200A. Therefore, for brevity, some descriptions are not repeated.

As shown in FIG. 3A, the memory device 300A includes the memory blocks BK1 and BK2. The memory block BK1 includes the sub-blocks SBK1_1-SBK1_8. The memory block BK2 includes sub-blocks SBK2_1-SBK2_8. The sub-blocks SBK1_1-SBK1_8 include the memory strings MS1_1-MS1_8, respectively. The sub-blocks SBK2_1-SBK2_8 include the memory strings MS2_1-MS2_8, respectively. Each of the memory strings MS1_1-MS2_8 is configured to receive the word line signals WL0-WL191.

In the embodiment shown in FIG. 3A, the memory device 300A performs the read operation to the switch elements corresponding to the word line signal WL191. Correspondingly, the word line signal WL191 has the read voltage level VREAD, and each of the word line signals WL0-WL190 has the pass voltage level VPASS. The store value of the stored data of the memory blocks BK1 and BK2 can be equal to one of the store value 1 to the store value 16.

FIG. 3B is a schematic diagram of a memory device 300B, illustrated according to some embodiments of present disclosure. Referring to FIG. 2A, FIG. 2B and FIG. 3B, the memory device 300B is an alternative embodiment of the memory device 200A. Therefore, for brevity, some descriptions are not repeated.

As shown in FIG. 3B, the memory device 300B includes the memory blocks BK1-BK32. The memory block BK1 includes the sub-blocks SBK1_1-SBK1_8. The memory block BK2 includes sub-blocks SBK2_1-SBK2_8, and so on. The memory block BK10 includes sub-blocks SBK10_1-SBK10_8. The memory block BK32 includes sub-blocks SBK32_1-SBK32_8. The sub-blocks SBK1_1-SBK32_8 include the memory strings MS1_1-MS32_8, respectively. The sub-blocks SBK2_1-SBK32_8 include the memory strings MS2_1-MS32_8, respectively. The memory strings MS2_1-MS32_8 are configured to receive the string select line signals SSL1_1-SSL32_8. Each of the memory strings MS1_1-MS32_8 is configured to receive the word line signals WL0-WL191.

In the embodiment shown in FIG. 3B, the memory device 300B performs the read operation to the switch elements corresponding to the word line signal WL191. Correspondingly, the word line signal WL191 has the read voltage level VREAD, and each of the word line signals WL0-WL190 has the pass voltage level VPASS. The store value of the stored data of the memory blocks BK1 and BK32 can be equal to one of the store value 1 to the store value 256.

In summary, in the embodiment shown in FIG. 3A the memory blocks BK1-BK2 can have the store values 0-16. In the embodiment shown in FIG. 2A the memory blocks BK1-BK4 can have the store values 0-32. In the embodiment shown in FIG. 3B the memory blocks BK1-BK32 can have the store values 0-256. Alternatively stated, by configuring various numbers of memory blocks, the memory device can store various store values.

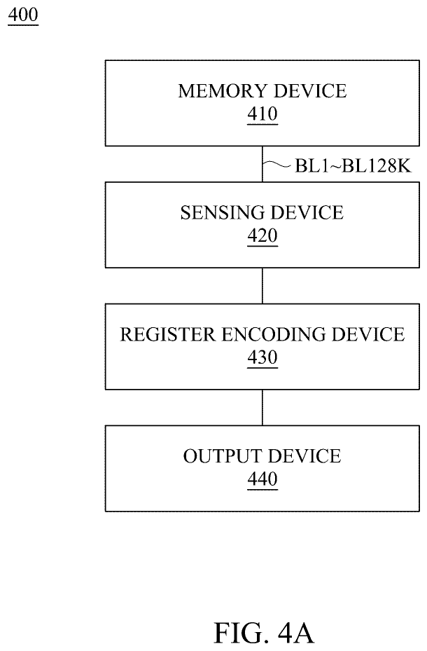

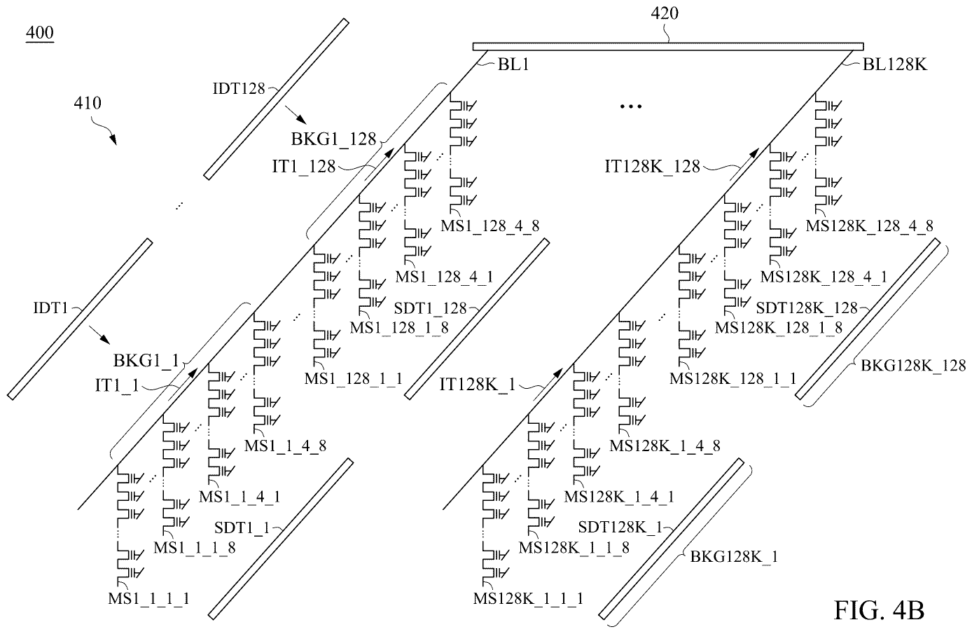

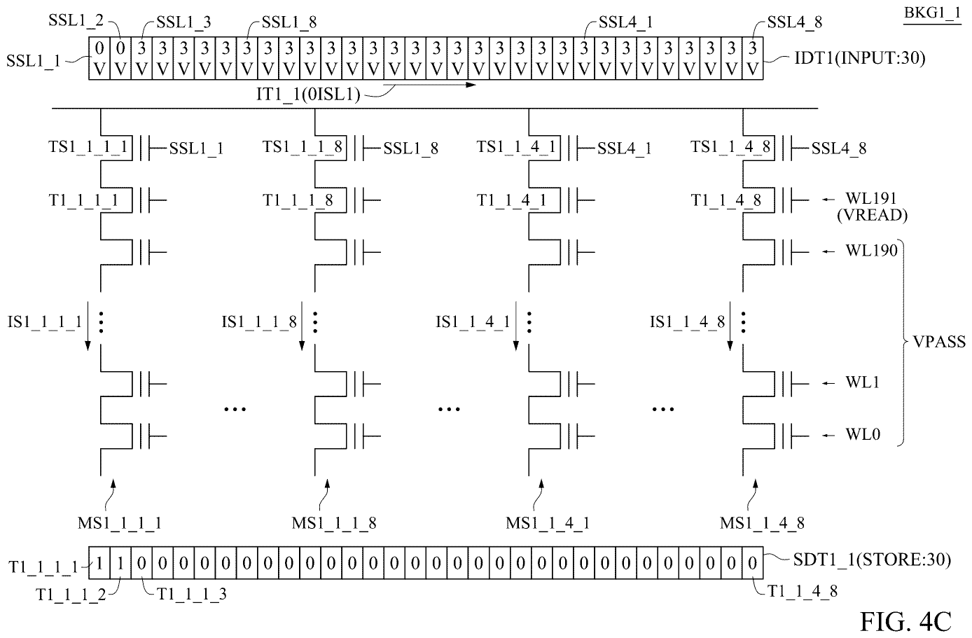

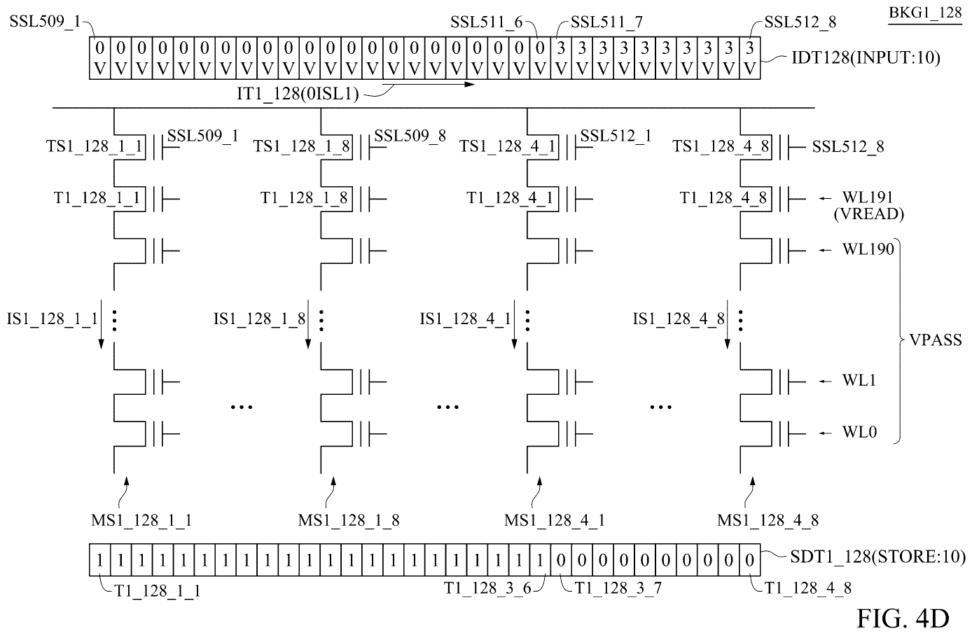

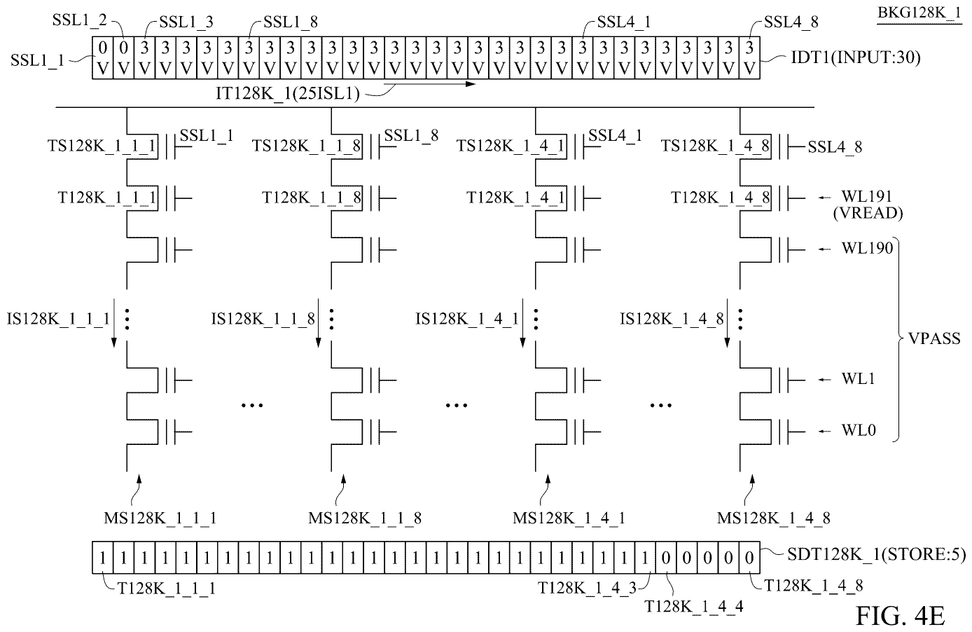

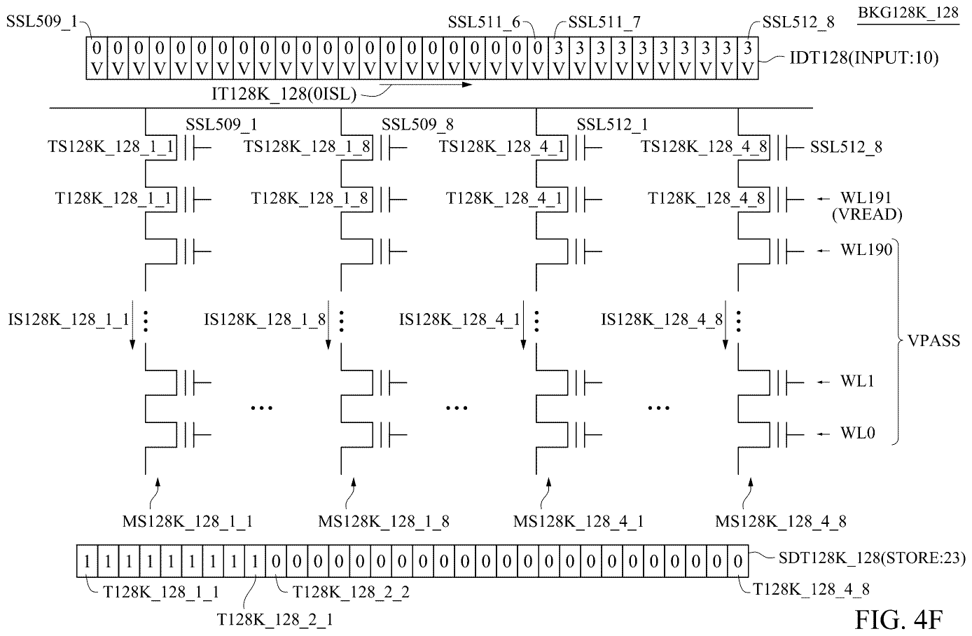

FIG. 4A is a schematic diagram of a memory system 400 illustrated according to some embodiments of present disclosure. As shown in FIG. 4A, the memory system 400 includes a memory device 410, a sensing device 420, a register encoding device 430 and an output device 440.

In some embodiments, the memory device 410 is configured to generate bit line signals BL1-BL128K, in which K in 128K represents one thousand. However, the present disclosure is not limited to this. In various embodiments, the memory device 410 can generate various quantities of bit line signals, that is, 128K can be substituted by other positive integers. The sensing device 420 can include a page buffer and a sensing amplifier, and configured to sense corresponding searching results of the bit line signals BL1-BL128K. The register encoding device 430 can includes cache registers and priority encoders. The output device 440 is configured to output the matching results of the memory device 410.

In some embodiments, the process performed by the register encoding device 430 to the bit line signals includes logic processes of AND logic, OR logic or counting, and also may include combining processes of the three logic processes described above. Referring to FIG. 1A to FIG. 4A, the register encoding device 430 can receive sense results from the memory device 100, 200A, 300A, 300B and/or 410, and controls sequencing (whether serial or parallel) and combines sense results to produce overall search results as the matching results outputted from the output device 440.

In some embodiments, the register encoding device 430 is further configured to perform priority encoding to the corresponding searching results of the bit line signals BL1-BL128K. For example, the register encoding device 430 collectively processes the corresponding searching results of the bit line signals BL1-BL128K, and preferentially select an address of a bit line signal corresponding to the best searching result (that is, the input value of the input data and the store value of the stored data are closest to each other).

FIG. 4B is a schematic diagram of further details of the memory system 400 shown in FIG. 4B, illustrated according to some embodiments of present disclosure. As shown in FIG. 4B, the memory device 410 includes memory block groups BKG1_1-BKG128K_128. However, the embodiments of present disclosure are not limited to this. In various embodiments, the memory device 410 can include various quantities of memory block groups. Alternatively stated, 128 can be substituted by other positive integers.

In some embodiments, each of the memory block groups BKG1_1-BKG128K_128 includes multiple blocks. Each block includes multiple sub-blocks. Further details of the memory block groups BKG1_1-BKG128K_128 are described below with the embodiments associated with FIG. 4C to FIG. 4F.

In some embodiments, the memory block groups BKG1_1-BKG128K_128 are configured to store stored data SDT1_1-SDT128K_128, respectively. The memory block group BKG1_1 is configured to compare the stored data SDT1_1 and input data IDT1 to generate a current signal IT1_1. The memory block group BKG2_1 is configured to compare the stored data SDT2_1 and the input data IDT1 to generate a current signal IT2_1, and so on. The memory block group BKG128K_1 is configured to compare the stored data SDT128K_1 and the input data IDT1 to generate a current signal IT128K_1.

Similarly, the memory block group BKG1_128 is configured to compare the stored data SDT1_128 and input data IDT128 to generate a current signal IT1_128. The memory block group BKG2_128 is configured to compare the stored data SDT2_128 and the input data IDT128 to generate a current signal IT2_128, and so on. The memory block group BKG128K_128 is configured to compare the stored data SDT128K_128 and the input data IDT128 to generate a current signal IT128K_128.

In some embodiments, a current level of the current signal IT1_1 is proportional to a difference between the stored data SDT1_1 and input data IDT1. A current level of the current signal IT2_1 is proportional to a difference between the stored data SDT2_1 and input data IDT1, and so on. A current level of the current signal IT128K_1 is proportional to a difference between the stored data SDT128K_1 and input data IDT1.

Similarly, a current level of the current signal IT1_128 is proportional to a difference between the stored data SDT1_128 and input data IDT128. A current level of the current signal IT2_128 is proportional to a difference between the stored data SDT2_128 and input data IDT128, and so on. A current level of the current signal IT128K_128 is proportional to a difference between the stored data SDT128K_128 and input data IDT128.

Referring to FIG. 2A, FIG. 2B and FIG. 4B, a configuration of each of the memory block groups BKG1_1-BKG128K_128 is similar to the configuration of the memory blocks BK1-BK4. A configuration of each of the current signals IT1_1-IT128K_128 is similar to the configuration of the current signal IT1. Therefore, for brevity some descriptions are not repeated.

In some embodiments, the memory block group BKG1_1-BKG1_128 are configured to sum the current signals IT1_1-IT1_128 to generate the bit line signal BL1. Alternatively stated, a current level of the bit line signal BL1 is equal to a summation of the current levels of the current signals IT1_1-IT1_128. Correspondingly, the current level of the bit line signal BL1 is equal to a summation of the differences between the stored data SDT1_1-SDT1_128 and the input data IDT1-IDT128.

Similarly, the memory block group BKG128K_1-BKG128K_128 are configured to sum the current signals IT128K_1-IT128K_128 to generate the bit line signal BL128K. Alternatively stated, a current level of the bit line signal BL128K is equal to a summation of the current levels of the current signals IT128K_1-IT128K_128. Correspondingly, the current level of the bit line signal BL128K is equal to a summation of the differences between the stored data SDT128K_1-SDT128K_128 and the input data IDT1-IDT128.

FIG. 4C is a schematic diagram of the memory block group BKG1_1 in the memory system 400, illustrated according to some embodiments of present disclosure. As shown in FIG. 4C, the memory block group BKG1_1 includes 32 memory strings MS1_1_1_1-MS1_1_4_8. The memory strings MS1_1_1_1-MS1_1_4_8 are configured to generate string current signals IS1_1_1_1-IS1_1_4_8, respectively. The memory block group BKG1_1 is configured to sum the string current signals IS1_1_1_1-IS1_1_4_8 to generate a current signal IT1_1. Each of the memory strings MS1_1_1_1-MS1_1_4_8 includes 192 switch elements configured to store the stored data bits and one switch element configured to receive the string select line signal.

Referring to FIG. 4C and FIG. 2B, configurations of the memory strings MS1_1_1_1-MS1_1_4_8 are similar with the configurations of the memory strings MS1_1-MS4_8. Configurations of the string current signals IS1_1_1_1-IS1_1_4_8 are similar with the configurations of the string current signals IS1_1-IS4_8. A configuration of the current signal IT1_1 is similar with the configuration of the current signal IT1. Therefore, for brevity, some descriptions are not repeated. For example, labels of the switch elements receiving the word line signals WL0-WL190 are not shown in FIG. 4C.

As shown in FIG. 4C, the memory string MS1_1_1_1 includes switch elements TS1_1_1_1, T1_1_1_1 and other 191 switch elements receiving the word line signals WL0-WL190. The memory string MS1_1_1_2 includes switch elements TS1_1_1_2, T1_1_1_2 and other 191 switch elements receiving the word line signals WL0-WL190, and so on. The memory string MS1_1_1_8 includes switch elements TS1_1_1_8, T1_1_1_8 and other 191 switch elements receiving the word line signals WL0-WL190.

Similarly, the memory string MS1_1_4_1 includes switch elements TS1_1_4_1, T1_1_4_1 and other 191 switch elements receiving the word line signals WL0-WL190. The memory string MS1_1_4_2 includes switch elements TS1_1_4_2, T1_1_4_2 and other 191 switch elements receiving the word line signals WL0-WL190, and so on. The memory string MS1_1_4_8 includes switch elements TS1_1_4_8, T1_1_4_8 and other 191 switch elements receiving the word line signals WL0-WL190.

Control terminals of the switch elements TS1_1_1_1-TS1_1_4_8 are configured to receive the string select line signals SSL1_1-SSL4_8, respectively. Each of control terminals of the switch elements T1_1_1_1-T1_1_4_8 is configured to receive the word line signal WL191.

In the embodiment shown in FIG. 4C, the switch elements T1_1_1_1-T1_1_4_8 are configured to store the stored data SDT1_1 having the store value 30. The string select line signals SSL1_1-SSL4_8 are configured to carry the input data IDT1 having the input value 30. The word line signal WL191 has the read voltage level VREAD, and each of the word line signals WL0-WL190 has the pass voltage level VPASS.

In response to the stored data SDT1_1 having the store value 30, each of the switch elements T1_1_1_1-T1_1_1_2 has the threshold voltage level LVT corresponding to the logic value 1, and each of the switch elements T1_1_1_3-T1_1_4_8 has the threshold voltage level HVT corresponding to the logic value 0. Correspondingly, each of the switch elements T1_1_1_3-T1_1_4_8 is turned off, such that each of the string current signals IS1_1_1_3-IS1_1_4_8 has the current level ISL2.

In response to the input data IDT1 having the input value 30, each of the string select line signals SSL1_1-SSL1_2 has the voltage level LVSSL, and each of the string select line signals SSL1_3-SSL4_8 has the voltage level HVSSL. Correspondingly, each of the switch elements TS1_1_1_1-TS1_1_1_2 is turned off, such that each of the string current signals IS1_1_1_1-IS1_1_1_2 has the current level ISL2. In which the voltage levels HVSSL and LVSSL can be 3 volt (3V) and 0 volt (0V), respectively.

In response to each of the string current signals IS1_1_1_1-IS1_1_4_8 has the current level ISL2, the current level of the current signal IT1_1 is equal to the current level ISL1 multiplied by 0, in which 0 represents the difference between the input value 30 of the input data IDT1 and the store value 30 of the stored data SDT1_1.

FIG. 4D is a schematic diagram of the memory block group BKG1_128 in the memory system 400, illustrated according to some embodiments of present disclosure. As shown in FIG. 4D, the memory block group BKG1_128 includes 32 memory strings MS1_128_1_1-MS1_128_4_8. The memory strings MS1_128_1_1-MS1_128_4_8 are configured to generate string current signals IS1_128_1_1-IS1_128_4_8, respectively. The memory block group BKG1_128 is configured to sum the string current signals IS1_128_1_1-IS1_128_4_8 to generate a current signal IT1_128.

Referring to FIG. 4D and FIG. 4C, configurations of the memory strings MS1_128_1_1-MS1_128_4_8 are similar with the configurations of the memory strings MS1_1_1_1-MS1_1_4_8. Therefore, for brevity, some descriptions are not repeated.

As shown in FIG. 4D, the memory string MS1_128_1_1 at least includes switch elements TS1_128_1_1 and T1_128_1_1. The memory string MS1_128_1_2 at least includes switch elements TS1_128_1_2 and T1_128_1_2, and so on. The memory string MS1_128_1_8 at least includes switch elements TS1_128_1_8 and T1_128_1_8.

Similarly, the memory string MS1_128_4_1 at least includes switch elements TS1_128_4_1 and T1_128_4_1. The memory string MS1_128_4_2 at least includes switch elements TS1_128_4_2 and T1_128_4_2, and so on. The memory string MS1_128_4_8 at least includes switch elements TS1_128_4_8 and T1_128_4_8.

Control terminals of the switch elements TS1_128_1_1-TS1_128_4_8 are configured to receive the string select line signals SSL509_1-SSL512_8, respectively. Each of control terminals of the switch elements T1_128_1_1-T1_128_4_8 is configured to receive the word line signal WL191.

In the embodiment shown in FIG. 4D, the switch elements T1_128_1_1-T1_128_4_8 are configured to store the stored data SDT1_128 having the store value 10. The string select line signals SSL509_1-SSL512_8 are configured to carry the input data IDT128 having the input value 10. The word line signal WL191 has the read voltage level VREAD, and each of the word line signals WL0-WL190 has the pass voltage level VPASS.

In response to the stored data SDT1_128 having the store value 10, each of the switch elements T1_128_1_1-T1_128_3_6 has the threshold voltage level LVT corresponding to the logic value 1, and each of the switch elements T1_128_3_7-T1_128_4_8 has the threshold voltage level HVT corresponding to the logic value 0. Correspondingly, each of the switch elements T1_128_3_7-T1_128_4_8 is turned off, such that each of the string current signals IS1_128_3_7-IS1_128_4_8 has the current level ISL2.

In response to the input data IDT128 having the input value 10, each of the string select line signals SSL509_1-SSL511_6 has the voltage level LVSSL, and each of the string select line signals SSL511_7-SSL512_8 has the voltage level HVSSL. Correspondingly, each of the switch elements TS1_128_1_1-TS1_128_3_6 is turned off, such that each of the string current signals IS1_128_1_1-IS1_128_3_6 has the current level ISL2.

In response to each of the string current signals IS1_128_1_1-IS1_128_4_8 has the current level ISL2, the current level of the current signal IT1_128 is equal to the current level ISL1 multiplied by 0, in which 0 represents the difference between the input value 10 of the input data IDT128 and the store value 10 of the stored data SDT1_128.

FIG. 4E is a schematic diagram of the memory block group BKG128K_1 in the memory system 400, illustrated according to some embodiments of present disclosure. As shown in FIG. 4E, the memory block group BKG128K_1 includes 32 memory strings MS128K_1_1_1-MS128K_1_4_8. The memory strings MS128K_1_1_1-MS128K_1_4_8 are configured to generate string current signals IS128K_1_1_1-IS128K_1_4_8, respectively. The memory block group BKG128K_1 is configured to sum the string current signals IS128K_1_1_1-IS128K_1_4_8 to generate a current signal IT128K_1.

Referring to FIG. 4E and FIG. 4C, configurations of the memory strings MS128K_1_1_1-MS128K_1_4_8 are similar with the configurations of the memory strings MS1_1_1_1-MS1_1_4_8. Therefore, for brevity, some descriptions are not repeated.

As shown in FIG. 4E, the memory string MS128K_1_1_1 at least includes switch elements TS128K_1_1_1 and T128K_1_1_1. The memory string MS128K_1_1_2 at least includes switch elements TS128K_1_1_2 and T128K_1_1_2, and so on. The memory string MS128K_1_1_8 at least includes switch elements TS128K_1_1_8 and T128K_1_1_8.

Similarly, the memory string MS128K_1_4_1 at least includes switch elements TS128K_1_4_1 and T128K_1_4_1. The memory string MS128K_1_4_2 at least includes switch elements TS128K_1_4_2 and T128K_1_4_2, and so on. The memory string MS128K_1_4_8 at least includes switch elements TS128K_1_4_8 and T128K_1_4_8.

Control terminals of the switch elements TS128K_1_1_1-TS128K_1_4_8 are configured to receive the string select line signals SSL1_1-SSL4_8, respectively. Each of control terminals of the switch elements T128K_1_1_1-T128K_1_4_8 is configured to receive the word line signal WL191.

In the embodiment shown in FIG. 4E, the switch elements T128K_1_1_1-T128K_1_4_8 are configured to store the stored data SDT128K_1 having the store value 5. The string select line signals SSL509_1-SSL512_8 are configured to carry the input data IDT1 having the input value 30. The word line signal WL191 has the read voltage level VREAD, and each of the word line signals WL0-WL190 has the pass voltage level VPASS.

In response to the stored data SDT128K_1 having the store value 5,each of the switch elements T128K_1_1_1-T128K_1_4_3 has the threshold voltage level LVT corresponding to the logic value 1, and each of the switch elements T128K_1_4_4-T128K_1_4_8 has the threshold voltage level HVT corresponding to the logic value 0. Correspondingly, each of the switch elements T128K_1_4_4-T128K_1_4_8 is turned off, such that each of the string current signals IS128K_1_4_4-IS128K_1_4_8 has the current level ISL2.

In response to the input data IDT1 having the input value 30, each of the string select line signals SSL1_1-SSL1_2 has the voltage level LVSSL, and each of the string select line signals SSL1_3-SSL4_8 has the voltage level HVSSL. Correspondingly, each of the switch elements TS128K_1_1_1-TS128K_1_1_2 is turned off, such that each of the string current signals IS128K_1_1_1-IS128K_1_1_2 has the current level ISL2.

At this moment, in response to the switch elements T128K_1_1_3-T128K_1_4_3 and TS128K_1_1_3-TS128K_1_4_3 being turned on, each of the string current signals IS128K_1_1_1-IS128K_1_4_3 has the current level ISL1. Alternatively stated, the memory block group BKG128K_1 generates 25string current signals having the current level ISL1. Correspondingly, the current level of the current signal IT128K_1 is equal to the current level ISL1 multiplied by 25, in which 25 represents the difference between the input value 30 of the input data IDT1 and the store value 5 of the stored data SDT128K_1.

FIG. 4F is a schematic diagram of the memory block group BKG128K_128 in the memory system 400, illustrated according to some embodiments of present disclosure. As shown in FIG. 4F, the memory block group BKG128K_128 includes 32 memory strings MS128K_128_1_1-MS128K_128_4_8. The memory strings MS128K_128_1_1-MS128K_128_4_8 are configured to generate string current signals IS128K_128_1_1-IS128K_128_4_8, respectively. The memory block group BKG128K_128 is configured to sum the string current signals IS128K_128_1_1-IS128K_128_4_8 to generate a current signal IT128K_128.

Referring to FIG. 4F and FIG. 4C, configurations of the memory strings MS128K_128_1_1-MS128K_128_4_8 are similar with the configurations of the memory strings MS1_1_1_1-MS1_1_4_8. Therefore, for brevity, some descriptions are not repeated.

As shown in FIG. 4F, the memory string MS128K_128_1_1 at least includes switch elements TS128K_128_1_1 and T128K_128_1_1. The memory string MS128K_128_1_2 at least includes switch elements TS128K_128_1_2 and T128K_128_1_2, and so on. The memory string MS128K_128_1_8 at least includes switch elements TS128K_128_1_8 and T128K_128_1_8.

Similarly, the memory string MS128K_128_4_1 at least includes switch elements TS128K_128_4_1 and T128K_128_4_1. The memory string MS128K_128_4_2 at least includes switch elements TS128K_128_4_2 and T128K_128_4_2, and so on. The memory string MS128K_128_4_8 at least includes switch elements TS128K_128_4_8 and T128K_128_4_8.

Control terminals of the switch elements TS128K_128_1_1-TS128K_128_4_8 are configured to receive the string select line signals SSL509_1-SSL512_8, respectively. Each of control terminals of the switch elements T128K_128_1_1-T128K_128_4_8 is configured to receive the word line signal WL191.

In the embodiment shown in FIG. 4F, the switch elements T128K_128_1_1-T128K_128_4_8 are configured to store the stored data SDT128K_128 having the store value 23. The string select line signals SSL509_1-SSL512_8 are configured to carry the input data IDT128 having the input value 10. The word line signal WL191 has the read voltage level VREAD, and each of the word line signals WL0-WL190 has the pass voltage level VPASS.

In response to the stored data SDT128K_128 having the store value 23, each of the switch elements T128K_128_1_1-T128K_128_2_1 has the threshold voltage level LVT corresponding to the logic value 1, and each of the switch elements T128K_128_2_2-T128K_128_4_8 has the threshold voltage level HVT corresponding to the logic value 0. Correspondingly, each of the switch elements T128K_128_2_2-T128K_128_4_8 is turned off, such that each of the string current signals IS128K_128_2_2-IS128K_128_4_8 has the current level ISL2.

In response to the input data IDT128 having the input value 10, each of the string select line signals SSL509_1-SSL511_6 has the voltage level LVSSL, and each of the string select line signals SSL511_7-SSL512_8 has the voltage level HVSSL. Correspondingly, each of the switch elements TS128K_128_1_1-TS128K_128_1_2 is turned off, such that each of the string current signals IS128K_128_1_1-IS128K_128_1_2 has the current level ISL2.

In response to each of the string current signals IS128K_128_1_1-IS128K_128_4_8 has the current level ISL2, the current level of the current signal IT128K_128 is equal to the current level ISL1 multiplied by 0. Alternatively stated, due to the store value 23 of the stored data SDT128K_128 is larger than the input value 10 of the input data IDT128, the current signal IT128K_128 has the zero current level.

In some embodiments, when a similarity between the input data IDT1-IDT128 and the stored data is higher, the current level of the corresponding bit line signal is smaller. For example, in response to a similarity between the input data IDT1-IDT128 and the stored data SDT1_1-SDT1_128 being higher than a similarity between the input data IDT1-IDT128 and the stored data SDT128K_1-SDT128K_128, the current level of the bit line signal BL1 is smaller than the current level of the bit line signal BL128K.

In summary, the memory system 400 can compare the input data IDT1-IDT128 with 128K stored data at the same time, to generate 128K bit line signals BL1-BL128K. As a result, the memory system 400 can determine similarities between the input data and the stored data according to the bit line signals BL1-BL128K.

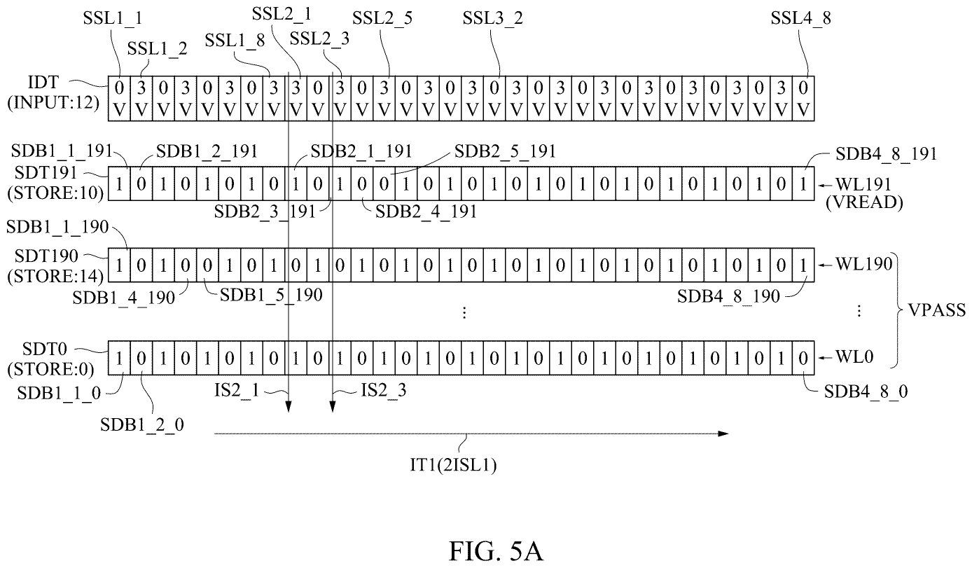

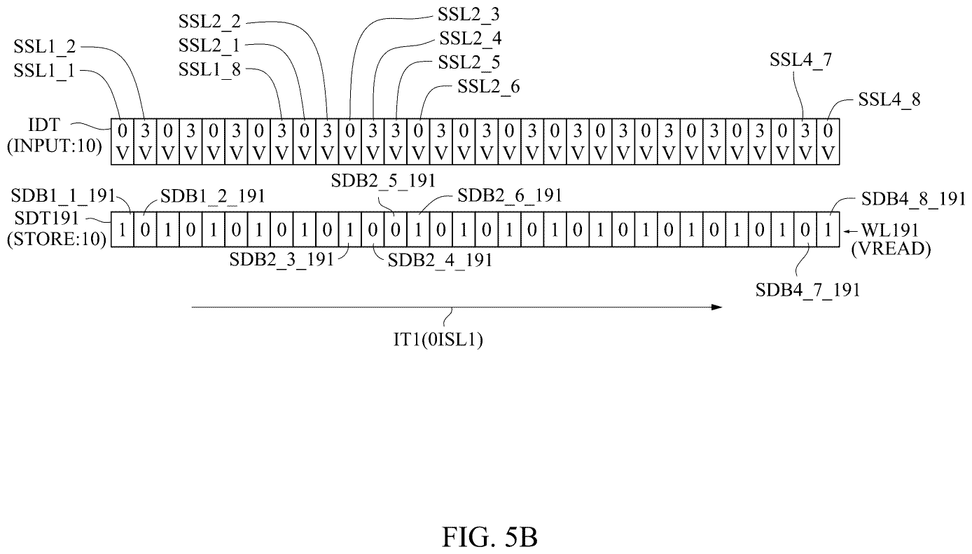

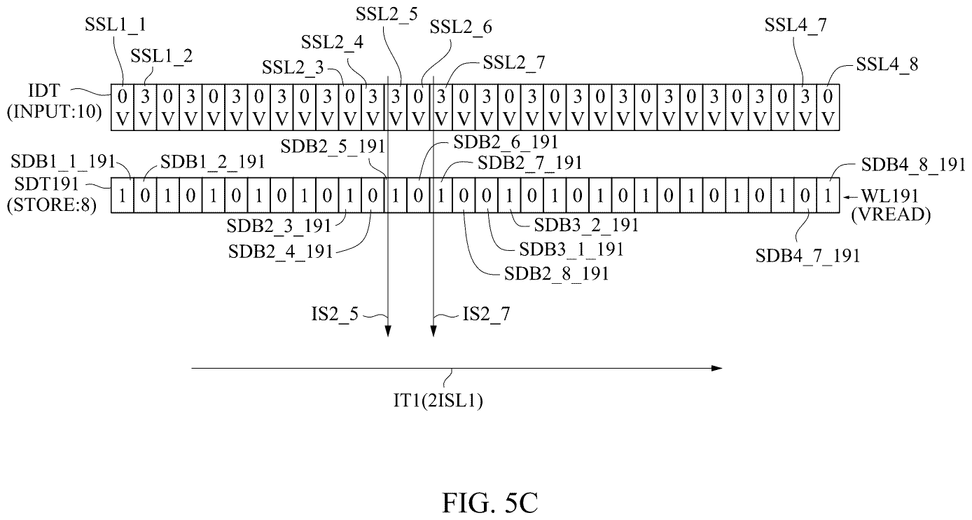

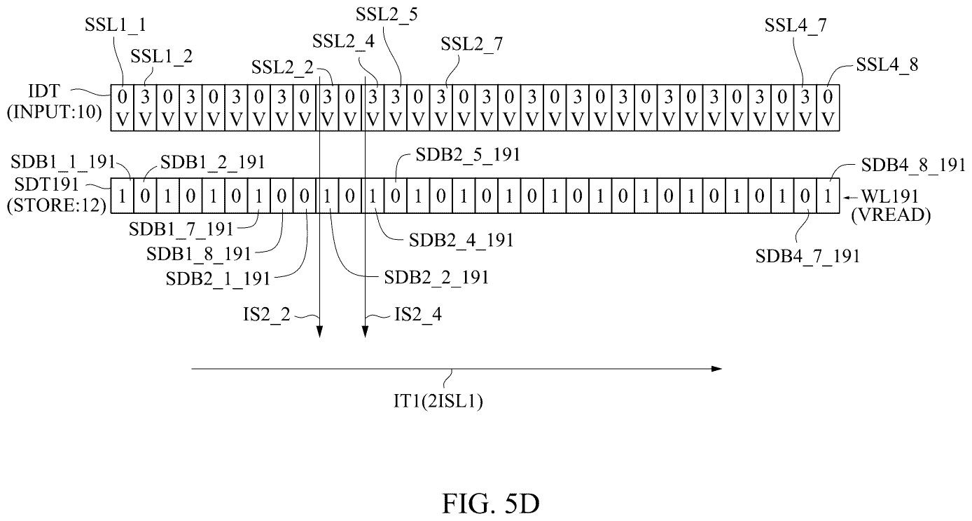

FIG. 5A is a schematic diagram of the stored data and the input data of the memory device 200A shown in FIG. 2A, illustrated according to some embodiments of present disclosure. Referring to FIG. 2C and FIG. 5A, the encoding method shown in FIG. 5A is an alternative embodiment shown in FIG. 2C.

In the embodiment shown in FIG. 5A, the memory device 200A encodes the stored data and the input data by paired switch elements and paired string select line signals. Specifically, the store value of the stored data is proportional to a quantity of the paired stored data bits having the logic values 0 and 1. The input value of the input data is proportional to a quantity of the paired string select line signals having the voltage levels HVSSL and LVSSL. In which, the voltage levels HVSSL and LVSSL can be equal to 3V and 0V, respectively.

For example, referring to FIG. 2B and FIG. 5A, in response to the input data IDT having the input value 12, the string select line signals SSL2_1-SSL4_8 have the voltage levels 3V, 0V, 3V, 0V, . . . , 3V and 0V, respectively, and the string select line signals SSL1_1-SSL1_8 have the voltage levels 0V, 3V, 0V, 3V, . . . , 0V and 3V, respectively. In which, the string select line signals SSL2_1-SSL4_8 correspond to 12 pairs of string select line signals having voltage levels 3V and 0V, and the string select line signals SSL1_1-SSL1_8 correspond to 4 pairs of string select line signals having voltage levels 0V and 3V.

On the other hand, in response to the stored data SDT191 having the store value 10, the stored data bits SDB2_5_191-SDB4_8_191 have the logic values 0, 1, 0, 1, . . . , 0 and 1, respectively, and the stored data bits SDB1_1_191-SDB2_4_191 have the logic values 1, 0, 1, 0, . . . , 1 and 0,respectively. In which, the stored data bits SDB2_5_191-SDB4_8_191 correspond to 10 pairs of stored data bits having the logic values 0 and 1, and the stored data bits SDB1_1_191-SDB2_4_191 correspond to 6 pairs of stored data bits having the logic values 1 and 0.

Similarly, in response to the stored data SDT190 having the store value 14, the stored data bits SDB1_5_190-SDB4_8_190 have the logic values 0, 1, 0, 1, . . . , 0 and 1, respectively, and the stored data bits SDB1_1_190-SDB1_4_190 have the logic values 1, 0, 1, 0, . . . , 1 and 0, respectively. In which, the stored data bits SDB1_5_190-SDB4_8_190 correspond to 14 pairs of stored data bits having the logic values 0 and 1, and the stored data bits SDB1_1_190-SDB1_4_190 correspond to 2 pairs of stored data bits having the logic values 1 and 0.

Similarly, in response to the stored data SDT0 having the store value 0,the stored data bits SDB1_1_0-SDB4_8_0 have the logic values 1, 0, 1, 0, . . . , 1 and 0, respectively. In which, the stored data bits SDB1_1_0-SDB4_8_0 correspond to 16 pairs of stored data bits having the logic values 1 and 0.

In the embodiment shown in FIG. 5A, the memory device 200A compares the stored data SDT191 and the input data IDT. Correspondingly, the word line signal WL191 has the read voltage level VREAD, and the line signals WL0-WL190 has the pass voltage level VPASS.

At this moment, in response to each of the string select line signals SSL1_1, SSL1_3, SSL1_5 and SSL1_7 having the voltage level 0V, each of the switch elements TS1_1, TS1_3, TS1_5 and TS1_7 is turned off. Correspondingly, each of the string current signals IS1_1, IS1_3, IS1_5 and IS1_7 has the current level ISL2.

In response to each of the string select line signals SSL2_2, SSL2_4, SSL2_6, . . . SSL4_6 and SSL4_8 having the voltage level 0V, each of the switch elements TS2_2, TS2_4, TS2_6, . . . TS4_6 and TS4_8 is turned off. Correspondingly, each of the string current signals IS2_2, IS2_4, IS2_6, . . . IS4_6 and IS4_8 has the current level ISL2.

On the other hand, in response to each of the stored data bits SDB1_2_191, SDB1_4_191, . . . , SDB2_2_191 and SDB2_4_191 having the logic value 0, each of the switch elements T1_2_191, T1_4_191, . . . , T2_2_191 and T2_4_191 is turned off. Correspondingly, each of the string current signals IS1_2, IS1_4, . . . IS2_2 and IS2_4 has the current level ISL2.

In response to each of the stored data bits SDB2_5_191, SDB2_7_191, . . . , SDB4_5_191 and SDB4_7_191 having the logic value 0, each of the switch elements T2_5_191, T2_7_191, . . . , T4_5_191 and T4_7_191 is turned off. Correspondingly, each of the string current signals IS2_5, IS2_7, . . . IS4_5 and IS4_7 has the current level ISL2.

At this moment, in response to the string select line signal SSL2_1 having the voltage level 3V and the stored data bit SDB2_1_191 having the logic value 1, the string current signal IS2_1 has the current level ISL1. Similarly, in response to the string select line signal SSL2_3 having the voltage level 3V and the stored data bit SDB2_3_191 having the logic value 1, the string current signal IS2_3 has the current level ISL1. Correspondingly, the current level of the current signal IT1 is equal to the current level ISL1 multiplied by 2, in which 2 represents a difference 2 between the store value 10 of the store data SDT191 and the input value 12 of the input data IDT.

For another example, the memory device 200A can also compares the stored data SDT190 and the input data IDT. Correspondingly, the word line signal WL190 has the read voltage level VREAD, and the line signals WL0-WL189 and WL191 has the pass voltage level VPASS.

At this moment, in response to the stored data bits having the logic value 0 and the string select line signals having the voltage level 0V, each of the string current signals IS1_1-IS1_5, IS1_7 and IS2_1-IS4_8 has the current level ISL2.

On the other hand, in response to each of the string select line signals SSL1_6 and SSL1_8 having the voltage level 3V and each of the stored data bits SDB1_6_191 and SDB1_8_191 having the logic value 1, each of the string current signals IS1_6 and IS1_8 has the current level ISL1. Similarly, in response to the string select line signals SSL2_3 having the voltage level 3V and the stored data bit SDB2_3_191 having the logic value 1, the string current signal IS2_3 has the current level ISL1. Correspondingly, the current level of the current signal IT1 is equal to the current level ISL1 multiplied by 2, in which 2 represents a difference 2 between the store value 14 of the store data SDT190 and the input value 12 of the input data IDT.

In some embodiments, the difference is an absolute value. Alternatively stated, the difference between the store value 14 and the input value 12 is equal to 2, and the difference between the store value 10 and the input value 12 is also equal to 2.

In summary, with the encoding method described above, no matter conditions of the stored data larger than the input data or conditions of the stored data smaller than the input data, the current level of the current signal IT1 can correspond to the difference between the stored data and the input data.

Referring to FIG. 5A, FIG. 3A and FIG. 3B, in various configurations, the store value of the stored data can have various ranges. In the embodiment shown in FIG. 3A, the stored data can have the store value 0 to the store value 8. In the embodiment shown in FIG. 5A, the stored data can have the store value 0 to the store value 16. In the embodiment shown in FIG. 3B, the stored data can have the store value 0 to the store value 128.

FIG. 5B is a schematic diagram of the stored data and the input data of the memory device 200A shown in FIG. 2A, illustrated according to some embodiments of present disclosure. In the embodiment shown in FIG. 5B, the voltage levels HVSSL and LVSSL are equal to 3V and 0V, respectively. The input data IDT has the input value 10. The stored data SDT191 has the store value 10. The word line signals WL191 has the read voltage level VREAD, to compare the input data IDT and the stored data SDT191.

In response to the input data IDT having the input value 10, the string select line signals SSL1_1-SSL2_4 have the voltage levels 0V, 3V, 0V, 3V, . . . , 0V and 3V, respectively, and the string select line signals SSL2_5-SSL4_8 have the voltage levels 3V, 0V, 3V, 0V, . . . , 3V and 0V, respectively, such that each of the switch elements TS1_1, TS1_3, . . . , TS2_1, TS2_3 and TS2_6, TS2_8, . . . , TS4_6, TS4_8 is turned off. Correspondingly, each of the string current signals IS1_1, IS1_3, . . . , IS2_1, IS2_3 and IS2_6, IS2_8, . . . , IS4_6, IS4_8 has the current level ISL2.

In response to the stored data SDT191 having the store value 10, the stored data bits SDB1_1_191-SDB2_4_191 have the logic values 1, 0, 1, 0, . . . , 1 and 0, respectively, and the stored data bits SDB2_5_191-SDB4_8_191 have the logic values 0, 1, 0, 1, . . . , 1 and 0, respectively, such that each of the switch elements T1_2_191, T1_4_191, . . . , T2_4_191 and T2_5_191, T2_7_191, . . . , T4_7_191 is turned off. Correspondingly, each of the string current signals IS1_2, IS1_4, . . . , IS2_4 and IS2_5, IS2_7, . . . , IS4_7 has the current level ISL2.

In summary, in response to the difference between the input value 10 of the input data IDT and the store value 10 of the stored data SDT191 being equal to 0, each of the string current signals IS1_1-IS4_8 has the current level ISL2, such that the current level of the current signal IT1 is equal to the current level ISL1 multiplied by 0.

FIG. 5C is a schematic diagram of the stored data and the input data of the memory device 200A shown in FIG. 2A, illustrated according to some embodiments of present disclosure. Referring to FIG. 5B and FIG. 5C, the condition shown in FIG. 5C is an alternative embodiment of the condition shown in FIG. 5B. Therefore, for brevity, some descriptions are not repeated. In the embodiment shown in FIG. 5C, the input data IDT has the input value 10. The stored data SDT191 has the store value 8.

In response to the stored data SDT191 having the store value 8, the stored data bits SDB1_1_191-SDB2_8_191 have the logic values 1, 0, 1, 0, . . . , 1 and 0, respectively, and the stored data bits SDB3_1_191-SDB4_8_191 have the logic values 0, 1, 0, 1, . . . , 1 and 0, respectively, such that each of the switch elements T1_2_191, T1_4_191, . . . , T2_8_191 and T3_1_191, T3_3_191, . . . , T4_7_191 is turned off. Correspondingly, each of the string current signals IS1_2, IS1_4, . . . , IS2_8 and IS3_1, IS3_3, . . . , IS4_7 has the current level ISL2.

At this moment, in response to the string select line signal SSL2_5 having the voltage level 3V and the switch element T2_5_191 turned on, the string current signal IS2_5 has the current level ISL1. Similarly, in response to the string select line signal SSL2_7 having the voltage level 3V and the switch element T2_7_191 turned on, the string current signal IS2_7 has the current level ISL1.

In summary, in response to the difference between the input value 10 of the input data IDT and the store value 8 of the stored data SDT191 being equal to 2, each of the string current signals IS1_1-IS2_4, IS2_6 and IS2_8-IS4_8 has the current level ISL2, and each of the string current signals IS2_5 and IS2_7 has the current level ISL1, such that the current level of the current signal IT1 is equal to the current level ISL1 multiplied by 2.

FIG. 5D is a schematic diagram of the stored data and the input data of the memory device 200A shown in FIG. 2A, illustrated according to some embodiments of present disclosure. Referring to FIG. 5B and FIG. 5D, the condition shown in FIG. 5D is an alternative embodiment of the condition shown in FIG. 5B. Therefore, for brevity, some descriptions are not repeated. In the embodiment shown in FIG. 5D, the input data IDT has the input value 10. The stored data SDT191 has the store value 12.

In response to the stored data SDT191 having the store value 12, the stored data bits SDB1_1_191-SDB1_8_191 have the logic values 1, 0, 1, 0, . . . , 1 and 0, respectively, and the stored data bits SDB2_1_191-SDB4_8_191 have the logic values 0, 1, 0, 1, . . . , 1 and 0, respectively, such that each of the switch elements T1_2_191, T1_4_191, . . . , T1_8_191 and T2_1_191, T3_3_191, . . . , T4_7_191 is turned off. Correspondingly, each of the string current signals IS1_2, IS1_4, . . . , IS1_8 and IS2_1, IS3_3, . . . , IS4_7 has the current level ISL2.

At this moment, in response to the string select line signal SSL2_2 having the voltage level 3V and the switch element T2_2_191 turned on, the string current signal IS2_2 has the current level ISL1. Similarly, in response to the string select line signal SSL2_4 having the voltage level 3V and the switch element T2_4_191 turned on, the string current signal IS2_4 has the current level ISL1.

In summary, in response to the difference between the input value 10 of the input data IDT and the store value 12 of the stored data SDT191 being equal to 2, each of the string current signals IS1_1-IS2_1, IS2_3 and IS2_5-IS4_8 has the current level ISL2, and each of the string current signals IS2_2 and IS2_4 has the current level ISL1, such that the current level of the current signal IT1 is equal to the current level ISL1 multiplied by 2.

Referring to FIG. 2B and FIG. 5B to FIG. 5D, the conditions shown in FIG. 5B, FIG. 5C and FIG. 5D correspond to the conditions of the store value being equal to, smaller than and larger than the input value, respectively. In the embodiment shown in FIG. 5B, each of the switch elements T2_4_191 and T2_5_191 is turned off, such that each of the string current signals IS2_4 and IS2_5 has the current level ISL2 (that is, the zero current level). In the embodiment shown in FIG. 5C, the switch element T2_5_191 is turned off, such that the string current signal IS2_5 has the current level ISL1. In the embodiment shown in FIG. 5D, the switch element T2_4_191 is turned off, such that the string current signal IS2_4 has the current level ISL1.

As a result, in the condition of the store value not equal to the input value, the memory device 200A generates at least one string current signal having the current level ISL1, such that the current level of the current signal IT1 is larger than the zero current level.

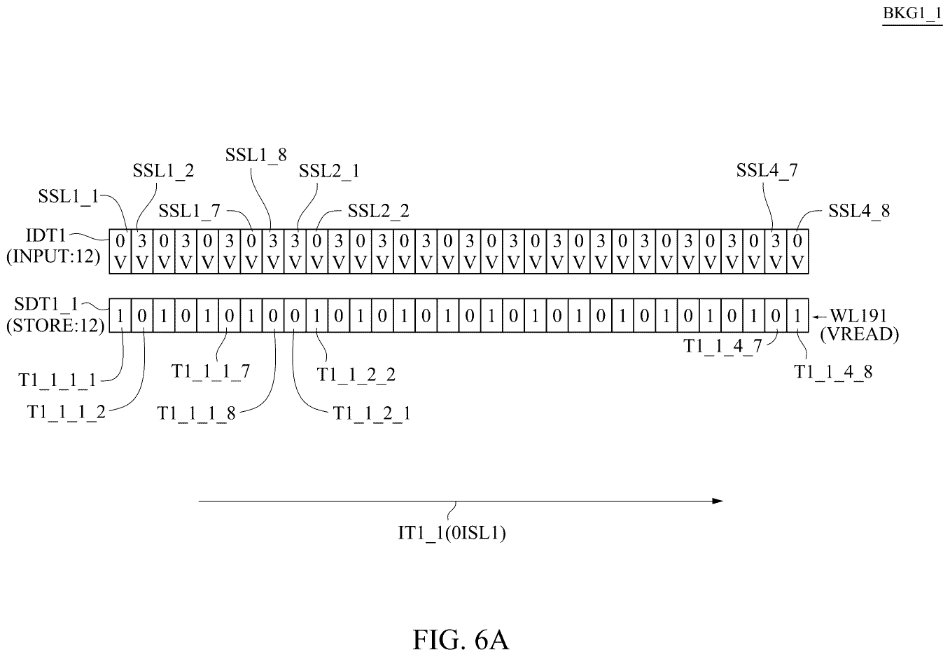

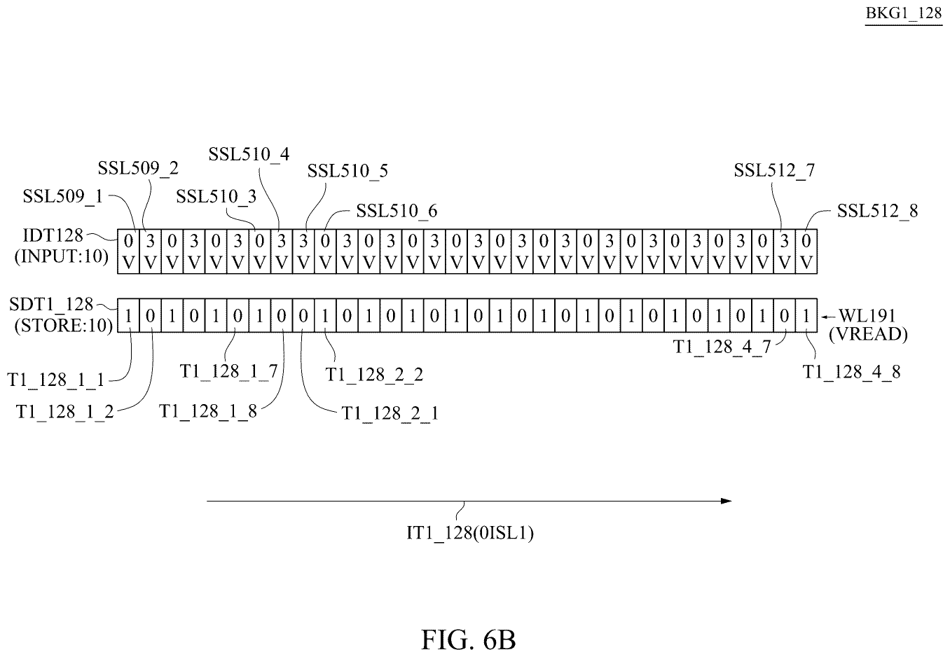

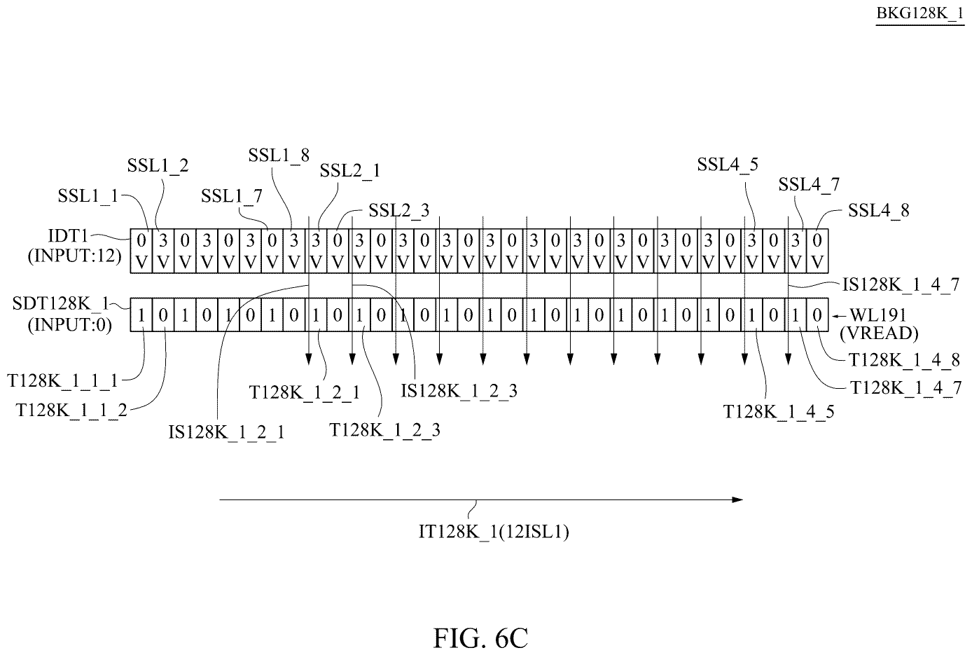

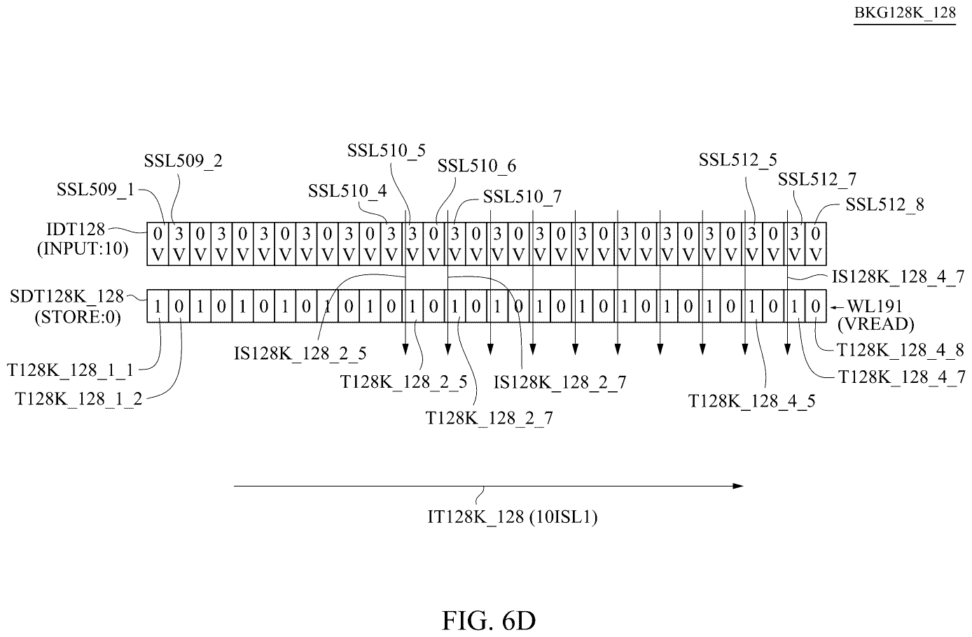

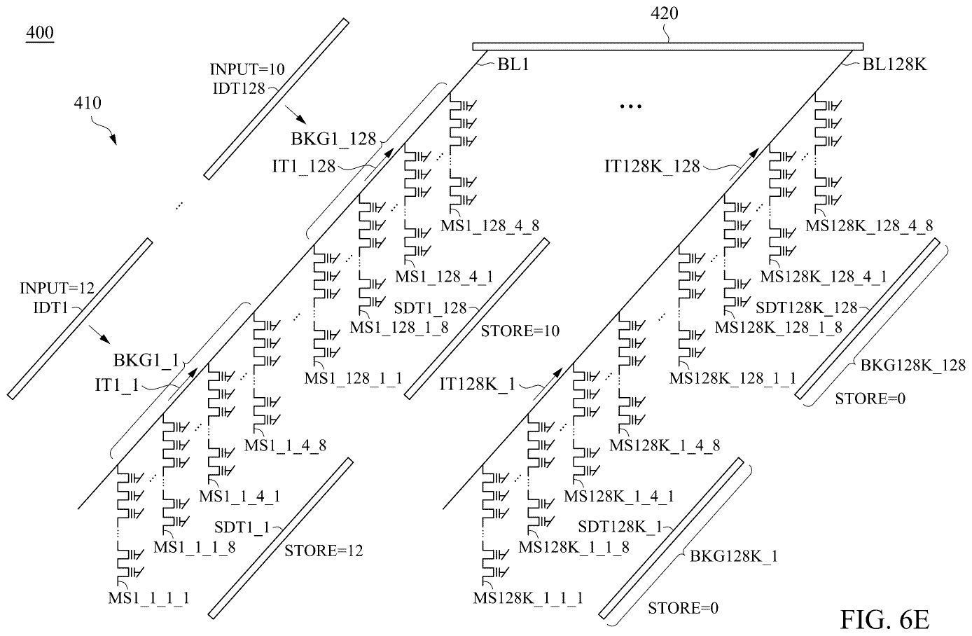

Referring to FIG. 4B and FIG. 5B to FIG. 5D, the memory system 400 can also generate the bit line signals BL1-BL128K according to the encoding method shown in FIG. 5A to FIG. 5D. Further details are described below in the embodiments shown in FIG. 6A to FIG. 6D.

FIG. 6A is a schematic diagram of the memory block group BKG1_1 shown in FIG. 4C performing the search operation, illustrated according to some embodiments of present disclosure. The condition shown in FIG. 6A is an alternative embodiment of the condition shown in FIG. 4C. Therefore, for brevity, some descriptions are not repeated. In the embodiment shown in FIG. 6A, the input data IDT1 has the input value 12, and the stored data SDT1_1 has the store value 12. The word line signal WL191 has the read voltage level VREAD.

In response to the input data IDT1 having the input value 12, the string select signals SSL1_1-SSL1_8 have the voltage levels 0V, 3V, 0V, 3V, . . . , 0V and 3V, respectively, and the string select signals SSL2_1-SSL4_8 have the voltage levels 3V, 0V, 3V, 0V, . . . , 3V and 0V, respectively. Correspondingly, each of the switch elements TS1_1_1_1, TS1_1_1_3, TS1_1_1_5, TS1_1_1_7 and TS1_1_2_2, TS1_1_2_4, . . . , TS1_1_4_6, TS1_1_4_8 is turned off, such that each of the current signals IS1_1_1_1, IS1_1_1_3, IS1_1_1_5, IS1_1_1_7 and IS1_1_2_2, IS1_1_2_4, . . . , IS1_1_4_6, IS1_1_4_8 has the current level ISL2.

On the other hand, in response to the stored data SDT1_1 having the store value 12, the switch elements T1_1_1_1-T1_1_1_8 store the logic values 1, 0, 1, 0, . . . , 1, 0, respectively, and the switch elements T1_1_2_1-T1_1_4_8 store the logic values 0, 1, 0, 1, . . . , 0, 1, respectively. Alternatively stated, each of the switch elements T1_1_1_2, T1_1_1_4, T1_1_1_6, T1_1_1_8 and T1_1_2_1, T1_1_2_3, . . . , T1_1_4_5, T1_1_4_7 is turned off, such that each of the string current signals IS1_1_1_2, IS1_1_1_4, IS1_1_1_6, IS1_1_1_8 and IS1_1_2_1, IS1_1_2_3, . . . , IS1_1_4_5, IS1_1_4_7 has the current level ISL2.

In summary, in response to the difference between the input value 12 of the input data IDT1 and the store value 12 of the stored data SDT1_1 being equal to 0, each of the string current signals IS1_1_1_1-IS1_1_4_8 has the current level ISL2, such that the current level of the current signal IT1_1 is equal to the current level ISL1 multiplied by 0.

FIG. 6B is a schematic diagram of the memory block group BKG1_128 shown in FIG. 4D performing the search operation, illustrated according to some embodiments of present disclosure. The condition shown in FIG. 6B is an alternative embodiment of the condition shown in FIG. 4D. Therefore, for brevity, some descriptions are not repeated. In the embodiment shown in FIG. 6B, the input data IDT128 has the input value 10, and the stored data SDT1_128 has the store value 10. The word line signal WL191 has the read voltage level VREAD.

In response to the input data IDT128 having the input value 10, the string select signals SSL509_1-SSL510_4 have the voltage levels 0V, 3V, 0V, 3V, . . . , 0V and 3V, respectively, and the string select signals SSL510_1-SSL512_8 have the voltage levels 3V, 0V, 3V, 0V, . . . , 3V and 0V, respectively. Correspondingly, each of the switch elements TS1_128_1_1, TS1_128_1_3, . . . , TS1_128_2_1, TS1_128_2_3 and TS1_128_2_6, TS1_128_2_8, . . . , TS1_128_4_6, TS1_128_4_8 is turned off, such that each of the current signals IS1_128_1_1, IS1_128_1_3, . . . , IS1_128_2_1, IS1_128_2_3 and IS1_128_2_6, IS1_128_2_8, . . . , IS1_128_4_6, IS1_128_4_8 has the current level ISL2.

On the other hand, in response to the stored data SDT1_128 having the store value 10, the switch elements T1_128_1_1-T1_128_2_4 store the logic values 1, 0, 1, 0, . . . , 1, 0, respectively, and the switch elements T1_128_2_5-T1_128_4_8 store the logic values 0, 1, 0, 1, . . . , 0, 1, respectively. Alternatively stated, each of the switch elements T1_128_1_2, T1_128_1_4, . . . , T1_128_2_2, T1_128_2_4 and T1_128_2_5, T1_128_2_7, . . . , T1_128_4_5, T1_128_4_7 is turned off, such that each of the string current signals IS1_128_1_2, IS1_128_1_4, . . . , IS1_128_2_2, IS1_128_2_4 and IS1_128_2_5, IS1_128_2_7, . . . , IS1_128_4_5, IS1_128_4_7 has the current level ISL2.

In summary, in response to the difference between the input value 12 of the input data IDT1 and the store value 12 of the stored data SDT1_128 being equal to 0, each of the string current signals IS1_128_1_1-IS1_128_4_8 has the current level ISL2, such that the current level of the current signal IT1_128 is equal to the current level ISL1 multiplied by 0.

FIG. 6C is a schematic diagram of the memory block group BKG128K_1 shown in FIG. 4E performing the search operation, illustrated according to some embodiments of present disclosure. The condition shown in FIG. 6C is an alternative embodiment of the condition shown in FIG. 4E. Therefore, for brevity, some descriptions are not repeated. In the embodiment shown in FIG. 6C, the input data IDT1 has the input value 12, and the stored data SDT128K_1 has the store value 0. The word line signal WL191 has the read voltage level VREAD.

Referring to FIG. 6A and FIG. 6C, the condition of the input data IDT1 having the input value 12 is described above in the embodiment of FIG. 6A. Therefore, for brevity, some descriptions are not repeated.

On the other hand, in response to the stored data SDT128K_1 having the store value 0, the switch elements T128K_1_1_1-T128K_1_4_8 store the logic values 1, 0, 1, 0, . . . , 1, 0, respectively. Alternatively stated, each of the switch elements T128K_1_1_2, T128K_1_1_4, . . . , T128K_1_4_6 and T128K_1_4_8 is turned off, such that each of the string current signals IS128K_1_1_2, IS128K_1_1_4, . . . , IS128K_1_4_6 and IS128K_1_4_8 has the current level ISL2.

At this moment, in response to each of the 12 string select line signals SSL2_1, SSL2_3, . . . , SSL4_5 and SSL4_7 having the voltage level 3V and each of the 12 switch elements T128K_1_2_1, T128K_1_2_3, . . . , T128K_1_4_5 and T128K_1_4_7 is turned on, each of the 12 string current signals IS128K_1_2_1, IS128K_1_2_3, . . . , IS128K_1_4_5 and IS128K_1_4_7 has the current level ISL1.

In summary, in response to the difference between the input value 12 of the input data IDT1 and the store value 0 of the stored data SDT128K_1 being equal to 12, each of the 12 string current signals IS128K_1_2_1, IS128K_1_2_3, . . . , IS128K_1_4_5 and IS128K_1_4_7 has the current level ISL1, such that the current level of the current signal IT128K_1 is equal to the current level ISL1 multiplied by 12.

FIG. 6D is a schematic diagram of the memory block group BKG128K_128 shown in FIG. 4F performing the search operation, illustrated according to some embodiments of present disclosure. The condition shown in FIG. 6D is an alternative embodiment of the condition shown in FIG. 4F. Therefore, for brevity, some descriptions are not repeated. In the embodiment shown in FIG. 6D, the input data IDT128 has the input value 12, and the stored data SDT128K_128 has the store value 0. The word line signal WL191 has the read voltage level VREAD.

Referring to FIG. 6B and FIG. 6D, the condition of the input data IDT128 having the input value 10 is described above in the embodiment of FIG. 6B. Therefore, for brevity, some descriptions are not repeated.

On the other hand, in response to the stored data SDT128K_128 having the store value 0, the switch elements T128K_128_1_1-T128K_128_4_8 store the logic values 1, 0, 1, 0, . . . , 1, 0, respectively. Alternatively stated, each of the switch elements T128K_128_1_2, T128K_128_1_4, . . . , T128K_128_4_6 and T128K_128_4_8 is turned off, such that each of the string current signals IS128K_128_1_2, IS128K_128_1_4, . . . , IS128K_128_4_6 and IS128K_128_4_8 has the current level ISL2.

At this moment, in response to each of the 10 string select line signals SSL510_5, SSL510_7, . . . , SSL512_5 and SSL512_7 having the voltage level 3V and each of the 12 switch elements T128K_128_2_5, T128K_128_2_7, . . . , T128K_128_4_5 and T128K_128_4_7 is turned on, each of the 10 string current signals IS128K_128_2_5, IS128K_128_2_7, . . . , IS128K_128_4_5 and IS128K_128_4_7 has the current level ISL1.

In summary, in response to the difference between the input value 10 of the input data IDT128 and the store value 0 of the stored data SDT128K_128 being equal to 10, each of the 10 string current signals IS128K_128_2_5, IS128K_128_2_7, . . . , IS128K_128_4_5 and IS128K_128_4_7 has the current level ISL1, such that the current level of the current signal IT128K_128 is equal to the current level ISL1 multiplied by 10.

FIG. 6E is a schematic diagram of further details of the memory system 400 shown in FIG. 4A, illustrated according to some embodiments of present disclosure. The condition shown in FIG. 6E is an alternative embodiment of the condition shown in FIG. 4B. Therefore, for brevity, some descriptions are not repeated.

Compared to the condition shown in FIG. 4B, in the condition shown in FIG. 6E, the memory device 410 encodes the stored data and the input data by paired switch elements and paired string select line signals. Specific details of paired data input and storage are described above in the embodiments shown in FIG. 5A to FIG. 5D.

In the embodiments shown in FIG. 6E, the input data IDT1 and IDT128 have the input value 12 and the input value 10, respectively. The stored data SDT1_1 and SDT1_128 have the store value 12 and the store value 10, respectively. Each of the stored data SDT128K_1 and SDT128K_128 has the store value 0. Specific configurations of the input data and the stored data are described above in the embodiments shown in FIG. 6A to FIG. 6D.

Referring FIG. 6E and FIG. 4B, in the embodiments shown in FIG. 6E, the memory device 410 stores one stored data bit by paired two switch elements, and carries one input data bit by paired two string select line signals. In contrast, in the embodiments shown in FIG. 4B, the memory device 410 stores one stored data bit by one switch element, and carries one input data bit by one string select line signal. As a result, data resolutions are different.

For example, in the embodiments shown in FIGS. 6E, 32 string select line signals can carry 16 input data bits. In which 16 is equal to fourth power of 2. Correspondingly, the data resolution of the configuration shown in FIG. 6E is referred to as int 4. In contrast, in the embodiments shown in FIGS. 4B, 32 string select line signals can carry 32 input data bits. In which 32 is equal to fifth power of 2. Correspondingly, the data resolution of the configuration shown in FIG. 4B is referred to as int 5.

In some embodiments, the memory cells in present disclosure are referred to as in-memory searching (IMS) cells. In various embodiments, the IMS cells can be implemented by floating gate memory, split-gate memory, silicon-oxide-nitride-oxide-silicon (SONOS) memory, floating dot memory, dynamic random-access memory (DRAM) and/or ferroelectric field-effect transistor (FeFET).

In various embodiments, the memory devices described in the present disclosure can be implemented by various structures, such as 2D flash structure or 3D flash structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising a plurality of memory blocks configured to store first stored data, and configured to compare the first stored data and first input data to generate a first current signal, the plurality of memory blocks comprising:
a plurality of memory strings coupled with each other, and configured to generate a plurality of string current signals,
wherein the plurality of memory blocks are configured to sum the plurality of string current signals to generate the first current signal, and
a current level of the first current signal is proportional to a difference between an input value of the first input data and a stored value of the first stored data.

2. The memory device of claim 1, wherein the plurality of memory strings are configured to receive a plurality of string select line signals,
the plurality of string select line signals comprise a first string select line signal and a second string select line signal,
when the first input data has a first input value, each of the first string select line signal and the second string select line signal has a first voltage level,
when the first input data has a second input value, the first string select line signal and the second string select line signal have the first voltage level and a second voltage level, respectively, and
when the first input data has a third input value, each of the first string select line signal and the second string select line signal has the second voltage level.

3. The memory device of claim 2, wherein the second voltage level is smaller than the first voltage level, and
the second input value is smaller than the first input value and larger than the third input value.

4. The memory device of claim 1, wherein the first stored data at least comprises a first stored data bit and a second stored data bit,
the plurality of memory strings comprises a first switch element configured to store the first stored data bit and a second switch element configured to store the second stored data bit,
when the first stored data has a first store value, each of the first switch element and the second switch element has a first threshold voltage level,
when the first stored data has a second store value, the first switch element and the second switch element has the first threshold voltage level and a second threshold voltage level, respectively,
when the first stored data has a third store value, each of the first switch element and the second switch element has the second threshold voltage level.

5. The memory device of claim 4, wherein the second threshold voltage level is smaller than the first threshold voltage level, and
the second store value is smaller than the first store value and larger than the third store value.

6. The memory device of claim 1, wherein when the input value of the first input data and the store value of the first stored data have a first difference between, each string current signal in a first portion of the plurality of string current signals has a first current level, and
a quantity of the string current signals in the first portion is equal to the first difference.

7. The memory device of claim 6, wherein when the input value of the first input data and the store value of the first stored data have a second difference between, each string current signal in a second portion of the plurality of string current signals has a second current level, and
a quantity of the string current signals in the second portion is equal to the second difference, and
the second difference is larger than the first difference.

8. The memory device of claim 1, wherein the plurality of memory strings are configured to receive a plurality of string select line signals,
the plurality of string select line signals comprise a first string select line signal and a second string select line signal,
when the first input data has a first input value, the first string select line signal and the second string select line signal has a first voltage level and a second voltage level, respectively,
when the first input data has a second input value, the first string select line signal and the second string select line signal have the second voltage level and the first voltage level, respectively.

9. The memory device of claim 8, wherein the second voltage level is larger than the first voltage level, and
the second input value is larger than the first input value.

10. The memory device of claim 8, wherein the plurality of memory strings comprise:
a first switch element configured to receive the first string select line signal;
a second switch element configured to receive the second string select line signal;
a third switch element coupled in series with the first switch element; and
a fourth switch element coupled in series with the second switch element,
wherein when the first stored data has a first store value, the third switch element is turned off and the fourth switch element is turned on, and
when the first stored data has a second store value, the third switch element is turned on and the fourth switch element is turned off.

11. The memory device of claim 10, wherein the plurality of memory strings further comprise:
a fifth switch element configured to receive a third string select line signal in the plurality of string select line signals; and
a sixth switch element configured to receive a fourth string select line signal in the plurality of string select line signals,
wherein when the first input data has the first input value, the third string select line signal and the fourth string select line signal has the second voltage level and the first voltage level, respectively.

12. The memory device of claim 11, wherein the plurality of memory strings further comprise:
a seventh switch element coupled in series with the fifth switch element; and
an eighth switch element coupled in series with the sixth switch element,
wherein when the first stored data has a third store value, the seventh switch element is turned off and the eighth switch element is turned on, and
when the first stored data has the second store value, the seventh switch element is turned on and the eighth switch element is turned off.

13. A memory device, comprising:
a plurality of memory strings coupled with each other, configured to generate a plurality of string current signals, and configured to sum the plurality of string current signals to generate a first current signal,
wherein the plurality of memory strings comprise a first switch element group and a second switch element group,
the first switch element group is configured to receive a plurality of string select line signals,
the plurality of string select line signals are configured to carry first input data,
the second switch element group is configured to store first stored data, and
a current level of the first current signal is proportional to a difference between an input value of the first input data and a store value of the first stored data.

14. The memory device of claim 13, wherein the first switch element group comprises a first switch element and a second switch element,
the second switch element group comprises a third switch element and a fourth switch element, and
when each of the first switch element and the second switch element is turned on, in response to the input value equal to the store value, each of the third switch element and the fourth switch element is turned off.

15. The memory device of claim 14, wherein
when each of the first switch element and the second switch element is turned on, in response to the input value larger than the store value, the third switch element is turned on, and
when each of the first switch element and the second switch element is turned on, in response to the input value smaller than the store value, the fourth switch element is turned on.

16. A memory system, comprising:
a plurality of first memory block groups configured to generate a plurality of first current signals, and sum the plurality of first current signals to generate a first bit line signal; and
a plurality of second memory block groups configured to generate a plurality of second current signals, and sum the plurality of second current signals to generate a second bit line signal,
the plurality of first memory block groups comprise a third memory block group configured to store first stored data and generate a third current signal in the plurality of first current signals,
the plurality of second memory block groups comprise a fourth memory block group configured to store second stored data and generate a fourth current signal in the plurality of second current signals,
a current level of the third current signal is proportional to a first difference between a store value of the first stored data and an input value of first input data, and
a current level of the fourth current signal is proportional to a second difference between a store value of the second stored data and the input value of the first input data.

17. The memory system of claim 16, wherein in response to the first difference smaller than the second difference, the current level of the third current signal is smaller than the current level of the fourth current signal.

18. The memory system of claim 16, wherein the plurality of first memory block groups further comprise a fifth memory block group configured to store third stored data and generate a fifth current signal in the plurality of first current signals,
a current level of the fifth current signal is proportional to a third difference between a store value of the third stored data and an input value of second input data, and
in response to the third difference equal to the first difference, the current level of the fifth current signal is equal to the current level of the third current signal.

19. The memory system of claim 18, wherein the plurality of first memory block groups further comprise a sixth memory block group configured to store fourth stored data and generate a sixth current signal in the plurality of first current signals,
a current level of the sixth current signal is proportional to a fourth difference between a store value of the fourth stored data and the input value of the second input data, and
in response to the fourth difference larger than the second difference, the current level of the sixth current signal is larger than the current level of the fourth current signal.

20. The memory system of claim 19, wherein in response to the fourth difference smaller than the third difference, the current level of the sixth current signal is smaller than the current level of the fifth current signal.
